(19) United States
(12) Patent Application Publication
(10) Pub. No.: US 2026/0141929 A1
(43) Pub. Date: May 21, 2026

(54) SEMICONDUCTOR MEMORY DEVICE

(71) Applicant: Samsung Electronics Co., Ltd., Suwon-si (KR)

(72) Inventors: Seunghoon Kim, Suwon-si (KR); Minsoo Kim, Suwon-si (KR); Sujin Kang, Suwon-si (KR); Yongkwan Kim, Suwon-si (KR); Huijung Kim, Suwon-si (KR); Kiseok Lee, Suwon-si (KR)

(21) Appl. No.: 19/375,323

(22) Filed: Oct. 31, 2025

(30) Foreign Application Priority Data
Nov. 15, 2024 (KR) 10-2024-0163370

(51) Int. Cl. G11C 5/06; H01L 23/00; H01L 23/522; H01L 23/528; H10B 12/00; H10D 80/30

(52) U.S. Cl. CPC G11C 5/063; H10B 12/09; H10B 12/315; H10B 12/482; H10B 12/488; H10B 12/50; H10D 80/30; H10W 20/42; H10W 20/427; H10W 20/43; H10W 20/435; H10W 90/792

(57) ABSTRACT

Provided is a semiconductor memory device including a first word line stack including a plurality of first word lines, a second word line stack including a plurality of second word lines and overlapping the first word line stack in a vertical direction, a plurality of first word line contacts connected to the plurality of first word lines, a plurality of second word line contacts connected to the plurality of second word lines, a plurality of word line routing vias extending in the vertical direction, a plurality of word line routing lines connecting the plurality of word line routing vias to the plurality of second word line contacts, a plurality of first routing pads connected to the plurality of first word line contacts, and a plurality of second routing pads connected to the plurality of word line routing vias.

### CROSS-REFERENCE TO RELATED APPLICATION

This application is based on and claims priority under 35 U.S.C. § 119 to Korean Patent Application No. 10-2024-0163370, filed on Nov. 15, 2024, in the Korean Intellectual Property Office, the disclosure of which is incorporated by reference herein in its entirety.

### BACKGROUND

The inventive concept relates to a semiconductor memory device, and more particularly, to a three-dimensional semiconductor memory device including a plurality of memory cells arranged in three dimensions.

As electronic products are required to have smaller sizes, multi-functions, and higher performance, high-capacity semiconductor memory devices are required, and an increased degree of integration is required to provide high-capacity semiconductor memory devices. Because the degree of integration of semiconductor memory devices of the related art, which include a plurality of memory cells arranged in two dimensions, is mainly determined by the area occupied by a unit memory cell, the degree of integration of two-dimensional semiconductor memory devices has increased but is still limited. Accordingly, a three-dimensional semiconductor memory device, in which memory capacity is increased by stacking memory cells in a vertical direction above a substrate to include a plurality of memory cells arranged in three dimensions, has been proposed.

### SUMMARY

The inventive concept provides a three-dimensional semiconductor memory device having an increased degree of integration.

According to an aspect of the inventive concept, there is provided a semiconductor memory device having a memory cell region and a pad region that are arranged in a first horizontal direction, the semiconductor memory device including a first word line stack including a plurality of first word lines extending in the first horizontal direction, being spaced apart from each other in each of a second horizontal direction and a vertical direction, and including a plurality of first word line pad portions in the pad region, the second horizontal direction being orthogonal to the first horizontal direction, a second word line stack including a plurality of second word lines and overlapping the first word line stack in the vertical direction, the plurality of second word lines extending in the first horizontal direction, being spaced apart from each other in each of the second horizontal direction and the vertical direction, and including a plurality of second word line pad portions in the pad region, a plurality of first word line contacts extending in the vertical direction and having ends connected to the plurality of first word line pad portions, a plurality of second word line contacts extending in the vertical direction and having ends connected to the plurality of second word line pad portions, a plurality of word line routing vias extending in the vertical direction and being spaced apart from each of the plurality of first word lines and the plurality of second word lines, in the pad region, a plurality of word line routing lines connecting ends of the plurality of word line routing vias to other ends of the plurality of second word line contacts, a plurality of first routing pads connected to other ends of the plurality of first word line contacts, and a plurality of second routing pads connected to other ends of the plurality of word line routing vias.

According to another aspect of the inventive concept, there is provided a semiconductor memory device having a memory cell region and a pad region that are arranged in a first horizontal direction, the semiconductor memory device including a memory cell structure and a peripheral circuit structure stacked perpendicular to the memory cell structure and electrically connected to the memory cell structure, wherein the peripheral circuit structure includes a peripheral circuit substrate and a plurality of peripheral circuit transistors located on an active surface of the peripheral circuit substrate, and the memory cell structure includes a first word line stack including a plurality of first word lines extending in the first horizontal direction, being spaced apart from each other in each of a second horizontal direction and a vertical direction, and including a plurality of first word line pad portions in the pad region, the second horizontal direction being orthogonal to the first horizontal direction, a second word line stack including a plurality of second word lines and overlapping the first word line stack in the vertical direction, the plurality of second word lines extending in the first horizontal direction, being spaced apart from each other in each of the second horizontal direction and the vertical direction, and including a plurality of second word line pad portions in the pad region, a plurality of first word line contacts extending in the vertical direction and having ends connected to the plurality of first word line pad portions, a plurality of second word line contacts extending in the vertical direction and having ends connected to the plurality of second word line pad portions, a plurality of word line routing vias extending in the vertical direction and being spaced apart from each of the plurality of first word lines and the plurality of second word lines, in the pad region, a plurality of word line routing lines connecting ends of the plurality of word line routing vias to other ends of the plurality of second word line contacts, a plurality of first routing pads connected to other ends of the plurality of first word line contacts, and a plurality of second routing pads connected to other ends of the plurality of word line routing vias.

According to another aspect of the inventive concept, there is provided a semiconductor memory device having a memory cell region and a pad region that are arranged in a first horizontal direction, the semiconductor memory device including a memory cell structure and a peripheral circuit structure stacked perpendicular to the memory cell structure and electrically connected to the memory cell structure, wherein the peripheral circuit structure includes a peripheral circuit substrate and a plurality of peripheral circuit transistors located on an active surface of the peripheral circuit substrate, and the memory cell structure includes a first word line stack including a plurality of first word lines extending in the first horizontal direction, being spaced apart from each other in each of a second horizontal direction and a vertical direction, and including a plurality of first word line pad portions in the pad region, the second horizontal direction being orthogonal to the first horizontal direction, a second word line stack including a plurality of second word lines and overlapping the first word line stack in the vertical direction, the plurality of second word lines extending in the first horizontal direction, being spaced apart from each other in each of the second horizontal direction and the vertical direction, and including a plurality of second word line pad portions in the pad region, a plurality of first bit lines extending in the vertical direction between the plurality of first word lines, a plurality of second bit lines extending in the vertical direction between the plurality of second word lines, a plurality of first word line contacts connected to lower surfaces of the plurality of first word line pad portions and extending in the vertical direction, a plurality of second word line contacts connected to upper surfaces of the plurality of second word line pad portions and extending in the vertical direction, a plurality of word line routing vias extending in the vertical direction between first word lines spaced apart from each other in the second horizontal direction, among the plurality of first word lines, and between second word lines spaced apart from each other in the second horizontal direction, among the plurality of second word lines, in the pad region, a plurality of word line routing lines connecting upper ends of the plurality of second word line contacts to upper ends of the plurality of word line routing vias, a plurality of first routing pads connected to lower ends of the plurality of first word line contacts, and a plurality of second routing pads connected to lower ends of the plurality of word line routing vias and electrically connected to the plurality of second word line contacts, wherein the plurality of first word line contacts have tapered shapes in which horizontal widths of the plurality of first word line contacts increase away from the plurality of first word line pad portions, the plurality of second word line contacts have tapered shapes in which horizontal widths of the plurality of second word line contacts increase away from the plurality of second word line pad portions, and the plurality of word line routing vias have tapered shapes in which horizontal widths of the plurality of word line routing vias decrease from the plurality of word line routing lines to the plurality of second routing pads.

### BRIEF DESCRIPTION OF THE DRAWINGS

Embodiments will be more clearly understood from the following detailed description

taken in conjunction with the accompanying drawings in which:

FIG. 1 is an equivalent circuit diagram illustrating a memory cell array of a semiconductor memory device according to example embodiments;

FIG. 2 is a block diagram illustrating a semiconductor memory device according to example embodiments;

FIGS. 3A to 3E are plan layout views and cross-sectional views illustrating a semiconductor memory device according to example embodiments;

FIGS. 4A, 4B, and 4C are perspective views illustrating a memory cell included in a semiconductor memory device according to example embodiments;

FIGS. 5A and 5B are plan layout views illustrating a semiconductor memory device according to example embodiments;

FIG. 6 is a cross-sectional view illustrating a semiconductor memory device according to example embodiments;

FIGS. 7A and 7B are cross-sectional views illustrating a semiconductor memory device according to example embodiments;

FIGS. 8, 9A, 9B, 10, 11A, 11B, 12A, and 12B are cross-sectional views illustrating a method of manufacturing a semiconductor memory device, according to example embodiments;

FIG. 13 is a cross-sectional view illustrating a semiconductor memory device according to example embodiments;

FIGS. 14 to 18 are cross-sectional views illustrating a method of manufacturing a semiconductor memory device according to example embodiments;

FIGS. 19A to 19E are plan layout views and cross-sectional views illustrating a semiconductor memory device according to example embodiments;

FIGS. 20A and 20B are cross-sectional views illustrating a semiconductor memory device according to example embodiments;

FIGS. 21 to 25 are cross-sectional views illustrating a method of manufacturing a semiconductor memory device according to example embodiments;

FIG. 26 is a cross-sectional view illustrating a semiconductor memory device according to example embodiments;

FIGS. 27A and 27B are cross-sectional views illustrating a semiconductor memory device according to example embodiments; and

FIG. 28 is an equivalent circuit diagram illustrating a memory cell array of a semiconductor memory device according to example embodiments.

### DETAILED DESCRIPTION OF THE EMBODIMENTS

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Like reference characters refer to like elements throughout.

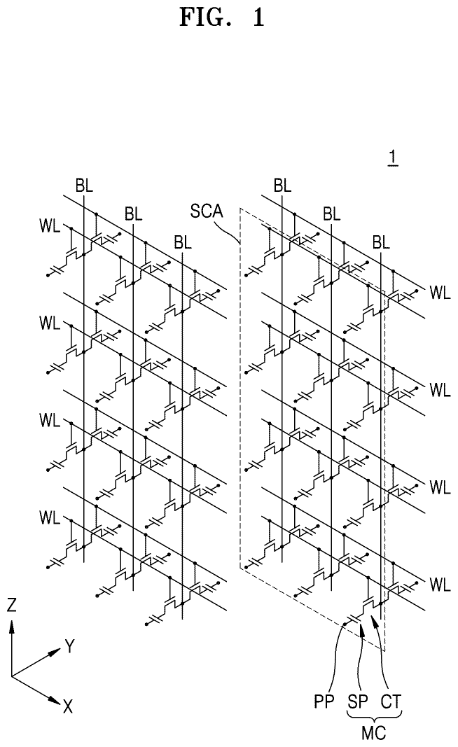

FIG. 1 is an equivalent circuit diagram illustrating a memory cell array of a semiconductor memory device 1 according to example embodiments.

Referring to FIG. 1, the memory cell array of the semiconductor memory device 1 according to embodiments may include a plurality of sub-cell arrays SCA. Each of the sub-cell arrays SCA may include a plurality of bit lines BL, a plurality of word lines WL, and a plurality of memory cells MC. Each of the plurality of memory cells MC may include a cell transistor CT and an information storage element SP. One cell transistor CT may be arranged between one word line WL and one bit line BL. The information storage element SP may be a memory element capable of storing data.

The word line WL may be a conductive pattern (e.g., a metal line) arranged above a substrate to be spaced apart from the substrate. The plurality of word lines WL may extend in a first horizontal direction (X direction). The word lines WL within one sub-cell array SCA may be spaced apart from each other in a vertical direction (Z direction). The bit line BL may extend in the vertical direction (Z direction) from the substrate. The bit lines BL within one sub-cell array SCA may be spaced apart from each other in the first horizontal direction (X direction).

In the memory cell array of the semiconductor memory device 1, the plurality of word lines WL may extend lengthwise in the first horizontal direction (X direction), and may be spaced apart from each other in each of a second horizontal direction (Y direction) and the vertical direction (Z direction). In the memory cell array of the semiconductor memory device 1, the plurality of bit lines BL may extend lengthwise in the vertical direction (Z direction), and may be spaced apart from each other in each of the first horizontal direction (X direction) and the second horizontal direction (Y direction). The plurality of sub-cell arrays SCA may be arranged in the second horizontal direction (Y direction). The second horizontal direction (Y direction) may be orthogonal to the first horizontal direction (X direction).

In some embodiments, the information storage element SP may be a memory element using a capacitor, a memory element using a magnetic tunnel junction pattern, or a memory element using a variable resistor including a phase change material. For example, the memory cell MC may be a dynamic random-access memory (DRAM) cell, and the information storage element SP may be a capacitor. In another embodiment, the information storage element SP may be a transistor capable of storing data together with the cell transistor CT. For example, the memory cell MC may be a two-transistor-zero-capacitor (2T-0C) DRAM cell. When the memory cell MC is a 2T-0C DRAM cell, the plurality of word lines WL may be some of a plurality of first conductive lines that extend lengthwise in the first horizontal direction (X direction) and are spaced apart from each other in each of the second horizontal direction (Y direction) and the vertical direction (Z direction), and the plurality of bit lines BL may be some of a plurality of second conductive lines that extend lengthwise in the vertical direction (Z direction) and are spaced apart from each other in each of the first horizontal direction (X direction) and the second horizontal direction (Y direction). The word line WL may be referred to as a first conductive line, and the bit line BL may be referred to as a second conductive line.

A gate of the cell transistor CT may be connected to the word line WL, and a source region of the cell transistor CT may be connected to the bit line BL. The information storage element SP may be connected to a drain region of the cell transistor CT. In some embodiments, the information storage element SP may be a capacitor including a first electrode, a second electrode, and a capacitor dielectric film arranged between the first electrode and the second electrode. In such embodiments, the first electrode of the capacitor may be connected to the drain region of the cell transistor CT, and the second electrode of the capacitor may be connected to a ground wiring PP.

The memory cell array of the semiconductor memory device 1 may include a plurality of sub-cell arrays SCA each including a plurality of memory cells MC arranged to be spaced apart from each other in rows and columns in the first horizontal direction (X direction) and the vertical direction (Z direction), respectively. The memory cell array may further include a plurality of bit lines BL connected to the cell transistors CT of the memory cells MC, which are arranged in the vertical direction (Z direction), extending in the vertical direction (Z direction), and arranged spaced apart from each other in the first horizontal direction (X direction). In addition, the memory cell array may include a plurality of word lines WL extending in the first horizontal direction (X direction) and arranged to be spaced apart from each other in the vertical direction (Z direction). The plurality of sub-cell arrays SCA may be arranged in parallel in the second horizontal direction (Y direction). The semiconductor memory device 1 may include a plurality of memory cell arrays.

The first horizontal direction (X direction), the second horizontal direction (Y direction), and the vertical direction (Z direction) may be referred to as a first direction, a second direction, and a third direction, respectively. Alternatively, the first horizontal direction (X direction), the vertical direction (Z direction), and the second horizontal direction (Y direction) may be referred to as a first direction, a second direction, and a third direction, respectively. The first direction, the second direction, and the third direction may be orthogonal to each other.

Two sub-cell arrays SCA adjacent to each other in the second horizontal direction (Y direction) may share bit lines BL. The source regions of the cell transistors CT respectively included in the two sub-cell arrays SCA may be connected to the bit lines BL shared by the two sub-cell arrays SCA. From each of the bit lines BL shared by the two sub-cell arrays SCA, the source regions and drain regions of the respective cell transistors CT and the respective information storage elements SP of the two sub-cell arrays SCA may be arranged in opposite directions. For example, the cell transistor CT of one of the two sub-cell arrays SCA and the cell transistor CT of the other sub-cell array SCA may be connected to one bit line BL shared by the two sub-cell arrays SCA. In such embodiments, the source region of the cell transistor CT, the drain region of the cell transistor CT, and the information storage element SP of one sub-cell array SCA may be sequentially arranged in the second horizontal direction (Y direction), and the source region of the cell transistor CT, the drain region of the cell transistor CT, and the information storage element SP of the other sub-cell array SCA may be sequentially arranged in a direction opposite to the second horizontal direction (Y direction). For example, between a pair of bit lines BL sequentially arranged adjacent to each other in the second horizontal direction (Y direction) among the plurality of bit lines BL, two memory cells MC may be arranged at the same vertical level in the second horizontal direction (Y direction).

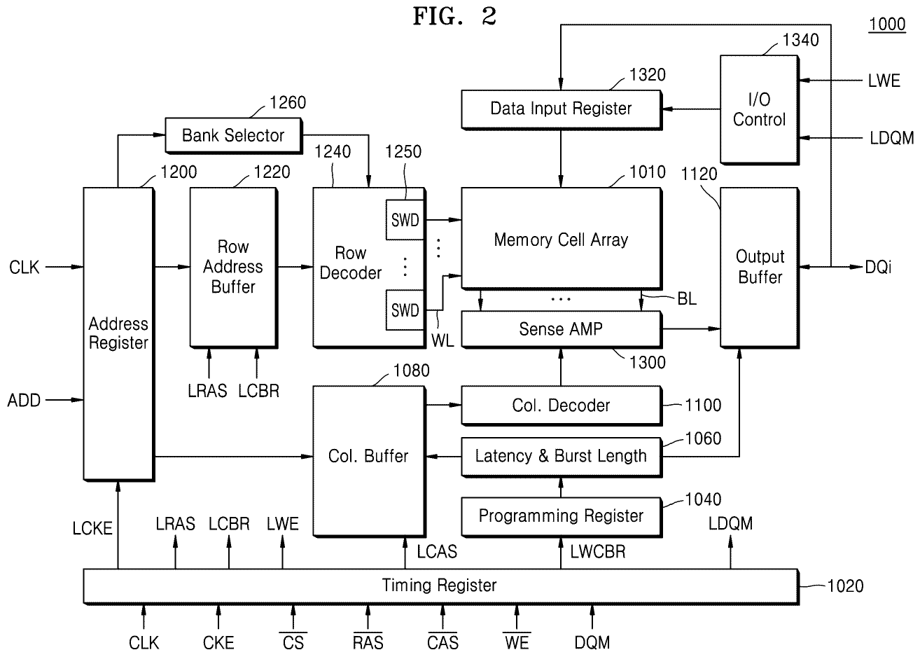

FIG. 2 is a block diagram illustrating a semiconductor memory device 1000 according to example embodiments.

Referring to FIG. 2, the semiconductor memory device 1000 may include a memory cell array 1010 including DRAM cells, each of which is a memory cell, and various circuit blocks for driving the DRAM cells. For example, a timing register 1020 may be activated when a chip select signal CS is changed from an inactive level (e.g., logic high) to an active level (e.g., logic low). The timing register 1020 may receive command signals, such as a clock signal CLK, a clock enable signal CKE, a chip select signal CS, a row address strobe signal RAS, a column address strobe signal CAS, a write enable signal WE, and a data input/output mask signal DQM, from the outside, and may process the received command signals to generate various internal command signals, such as low-power clock enable LCKE, low-active row address strobe LRAS, low-active CVR refresh LCBR, low-active write enable LWE, low-active column address strobe LCAS, low-active write CAS before RAS LWCBR, and low-active data input/output mask LDQM, for controlling the circuit blocks.

Some of the internal command signals generated by the timing register 1020 may be stored in a programming register 1040. For example, latency information or burst length information associated with data output may be stored in the programming register 1040. The internal command signals stored in the programming register 1040 may be provided to a latency/burst length controller 1060, and the latency/burst length controller 1060 may provide a control signal for controlling the latency or burst length of data output to a column decoder 1100 through a column address buffer 1080 or an output buffer 1120.

An address register 1200 may receive a clock signal CLK and an address signal ADD from the outside. A row address signal may be provided to a row decoder 1240 through a row address buffer 1220. Also, a column address signal may be provided to the column decoder 1100 through the column address buffer 1080. The row address buffer 1220 may further receive a refresh address signal generated by a refresh counter in response to refresh commands LRAS and LCBR, and may provide one of the row address signal and the refresh address signal to the row decoder 1240. Also, the address register 1200 may provide a bank signal for selecting a bank to a bank selector 1260.

The row decoder 1240 may decode the row address signal or the refresh address signal input received from the row address buffer 1220. The row decoder 1240 may include a plurality of sub-word line drivers 1250. The sub-word line driver 1250 may activate a word line WL of the memory cell array 1010. For example, each of the sub-word line drivers 1250 may activate a corresponding one of the word lines WL of the memory cell array 1010. The sub-word line drivers 1250 may be arranged in blocks at certain intervals within the row decoder 1240 so as to be adjacent to the memory cell array 1010. For example, the sub-word line driver 1250 may be arranged adjacent to an end of the memory cell array 1010 so as to be perpendicular to a sense amplifier 1300.

The column decoder 1100 may decode the column address signal, and may perform a selection operation on a bit line BL of the memory cell array 1010. For example, a column selection line may be applied to the semiconductor memory device 1000, and a selection operation may be performed through the column selection line.

The sense amplifier 1300 may amplify data of a memory cell selected by the row decoder 1240 and the column decoder 1100, and may provide the amplified data to the output buffer 1120. The output buffer 1120 may output output data DQi. Data to be written to a data cell may be provided to the memory cell array 1010 through a data input register 1320, and an input/output controller 1340 may control a data transmission operation through the data input register 1320.

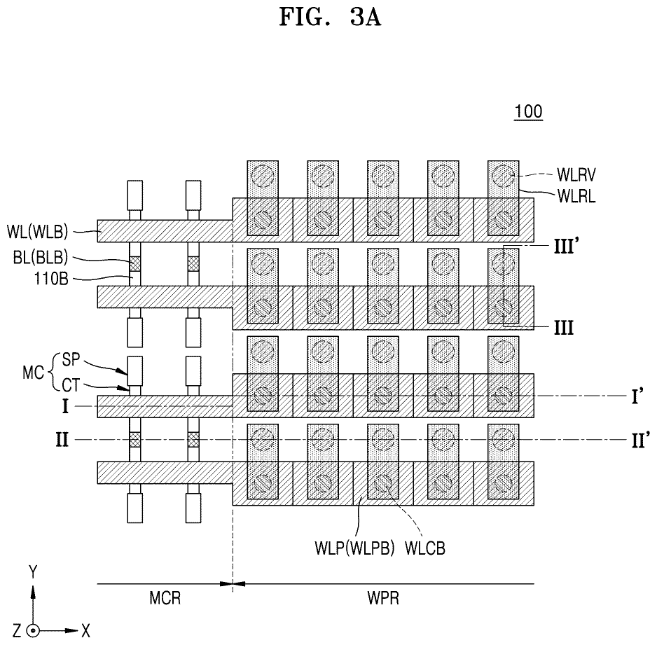

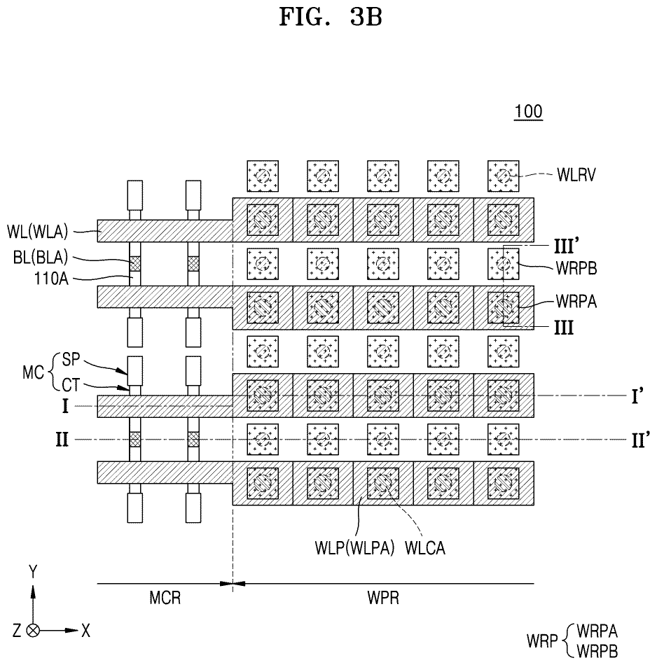

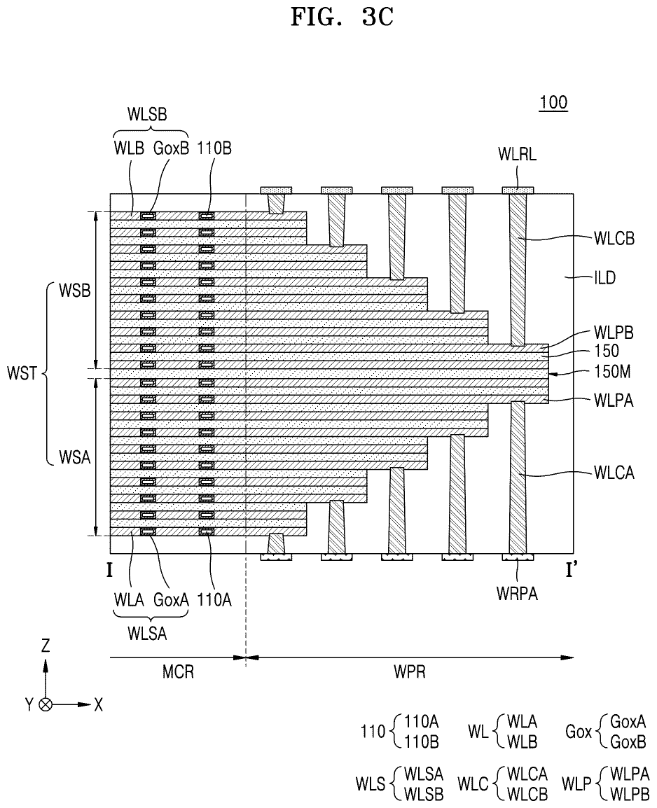

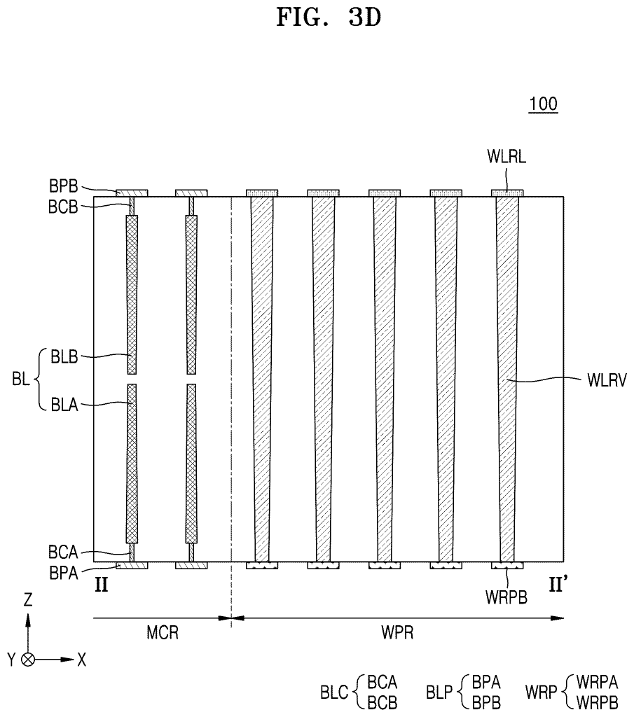

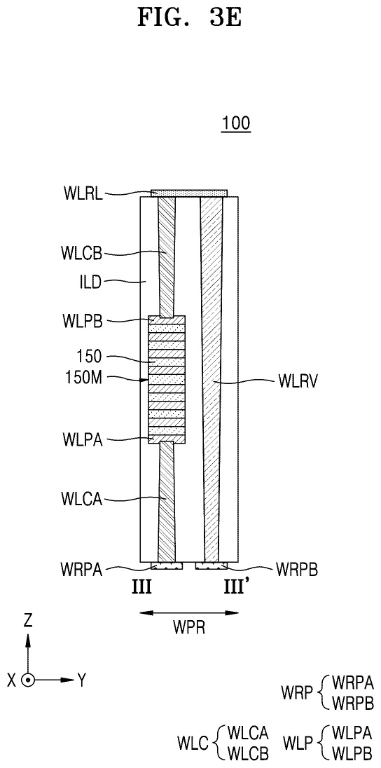

FIGS. 3A to 3E are plan layout views and cross-sectional views illustrating a semiconductor memory device 100 according to example embodiments. In detail, FIG. 3A is a top-down plan layout view of the semiconductor memory device 100 according to embodiments, FIG. 3B is a bottom-up plan layout view of the semiconductor memory device 100 according to embodiments, FIG. 3C is a cross-sectional view of the semiconductor memory device 100, taken along a line I-I′ of FIGS. 3A and 3B, FIG. 3D is a cross-sectional view of the semiconductor memory device 100, taken along a line II-II′ of FIGS. 3A and 3B, and FIG. 3E is a cross-sectional view of the semiconductor memory device 100, taken along a line III-III′ of FIGS. 3A and 3B.

Referring to FIGS. 3A to 3E together, the semiconductor memory device 100 may include a plurality of word lines WL extending lengthwise in a first horizontal direction (X direction) and being spaced apart from each other in each of a second horizontal direction (Y direction) and a vertical direction (Z direction). The second horizontal direction (Y direction) may be orthogonal to the first horizontal direction (X direction). The plurality of word lines WL may include a plurality of first word lines WLA and a plurality of second word lines WLB. The plurality of word lines WL may constitute a word line stack WST. The word line stack WST may include a first word line stack WSA and a second word line stack WSB that overlap each other in the vertical direction (Z direction). For example, the second word line stack WSB may be located above the first word line stack WSA. The first word line stack WSA may include the plurality of first word lines WLA among the plurality of word lines WL, and the second word line stack WSB may include the plurality of second word lines WLB among the plurality of word lines WL.

Herein, the first word line stack WSA and the second word line stack WSB may be referred to as a lower word line stack and an upper word line stack, respectively. Also, components related to the first word line stack WSA, such as those included in the first word line stack WSA or connected to the first word line stack WSA, may be referred to as “first” or “lower,” and components related to the second word line stack WSB, such as those included in the second word line stack WSB or connected to the second word line stack WSB, may be referred to as “second” or “upper.” For example, the first word line WLA included in the first word line stack WSA may also be referred to as a lower word line, and the second word line WLB included in the second word line stack WSB may also be referred to as an upper word line.

Among the plurality of first word lines WLA included in the first word line stack WSA, the first word lines WLA aligned in the vertical direction (Z direction) may have a staircase structure in which extension lengths of the first word lines WLA increase in the first horizontal direction (X direction) from lower sides to upper sides thereof in the vertical direction (Z direction). Among the plurality of second word lines WLB included in the second word line stack WSB, the second word lines WLB aligned in the vertical direction (Z direction) may have a staircase structure in which extension lengths of the second word lines WLB decrease in the first horizontal direction (X direction) from lower sides to upper sides thereof in the vertical direction (Z direction). That is, among the plurality of word lines WL, the word lines WL aligned in the vertical direction (Z direction) may have extension lengths that increase in the first horizontal direction (X direction) from lower sides to upper sides of the word lines WL, or from the upper sides to the lower sides thereof, and then decrease after reaching a maximum extension length. The staircase structure of the first word line stack WSA and the staircase structure of the second word line stack WSB may be mirror-symmetrical in the vertical direction (Z direction).

FIG. 3C shows that the uppermost first word line WLA and the lowermost second word line WLB that are aligned in the vertical direction (Z direction) have the same extension length in the first horizontal direction (X direction), but embodiments are not limited thereto. For example, the uppermost first word line WLA aligned in the vertical direction (Z direction) may have a greater extension length in the first horizontal direction (X direction) than the lowermost second word line WLB aligned in the vertical direction (Z direction). Alternatively, for example, the uppermost first word line WLA aligned in the vertical direction (Z direction) may have a smaller extension length in the first horizontal direction (X direction) than the lowermost second word line WLB aligned in the vertical direction (Z direction).

Among the plurality of first word lines WLA, the first word lines WLA that are at the same vertical level and arranged spaced apart from each other in the second horizontal direction (Y direction) may have the same extension length in the first horizontal direction (X direction), but are not limited thereto. For example, as long as the first word lines WLA aligned in the vertical direction (Z direction) among the plurality of first word lines WLA have increasing extension lengths in the first horizontal direction (X direction) from lower sides to upper sides thereof in the vertical direction (Z direction), the extension lengths of the first word lines WLA located at the same vertical level may or may not be the same. Among the plurality of second word lines WLB, the second word lines WLB that are at the same vertical level and arranged spaced apart from each other in the second horizontal direction (Y direction) may have the same extension length in the first horizontal direction (X direction), but are not limited thereto. For example, as long as the second word lines WLB aligned in the vertical direction (Z direction) among the plurality of second word lines WLB have decreasing extension lengths in the first horizontal direction (X direction) from lower sides to upper sides thereof in the vertical direction (Z direction), the extension lengths of the second word lines WLB located at the same vertical level may or may not be the same.

The semiconductor memory device 100 may have a memory cell region MCR and a pad region WPR that are arranged in the first horizontal direction (X direction). The plurality of word lines WL may include a plurality of word line pad portions WLP located in the pad region WPR. Each of the plurality of word line pad portions WLP refers to a portion of each of the plurality of word lines WL that does not overlap another word line WL above or below the word line WL at an end of the word line WL in the first horizontal direction (X direction). FIGS. 3A to 3C show that the plurality of word lines WL include a plurality of word line pad portions WLP located at ends thereof in the first horizontal direction (X direction), but embodiments are not limited thereto. In some embodiments, some of the plurality of word lines WL may each include a word line pad portion WLP at an end thereof in the first horizontal direction (X direction), and some other word lines WL may each include a word line pad portion WLP at the other end thereof in the first horizontal direction (X direction). For example, in FIG. 3C, among the plurality of word lines WL, the word line WL of which an end overlaps another word line WL thereabove and another word line WL therebelow in the first horizontal direction (X direction), such that a word line pad portion WLP is not located at the end thereof, may have a word line pad portion WLP located at the other end thereof.

The plurality of word line pad portions WLP may include a plurality of first word line pad portions WLPA included in the plurality of first word lines WLA, and a plurality of second word line pad portions WLPB included in the plurality of second word lines WLB. The first word line pad portion WLPA refers to a portion of each of the plurality of first word lines WLA that does not overlap another first word line WLA below the first word line WLA at an end of the first word line WLA in the first horizontal direction (X direction), and the second word line pad portion WLPB refers to a portion of each of the plurality of second word lines WLB that does not overlap another second word line WLB above the second word line WLB at an end of the second word line WLB in the first horizontal direction (X direction).

In some embodiments, a portion of each of the plurality of word lines WL located in the pad region WPR may have a greater horizontal width in the second horizontal direction (Y direction) than a portion of each of the plurality of word lines WL located in the memory cell region MCR. For example, the word line pad portion WLP may have a greater horizontal width in the second horizontal direction (Y direction) than a portion of the word line WL located in the memory cell region MCR. In some other embodiments, each of the plurality of word lines WL may have the same horizontal width in the second horizontal direction (Y direction) in the memory cell region MCR and the pad region WPR. For example, the word line pad portion WLP and a portion of the word line WL located in the memory cell region MCR may have the same horizontal width in the second horizontal direction (Y direction).

A plurality of word line contacts WLC may be connected to the plurality of word line pad portions WLP. The plurality of word line contacts WLC may include a plurality of first word line contacts WLCA and a plurality of second word line contacts WLCB. The first word line contact WLCA may be connected to a lower surface of the first word line pad portion WLPA, and may extend downward from the first word line pad portion WLPA to which the first word line contact WLCA is connected. For example, each of the first word line contacts WLCA may contact the lower surface of a corresponding one of the first word line pad portions WLPA. The second word line contact WLCB may be connected to an upper surface of the second word line pad portion WLPB, and may extend upward from the second word line pad portion WLPB to which the second word line contact WLCB is connected. For example, each of the second word line contacts WLCB may contact the upper surface of a corresponding one of the second word line pad portions WLPB. Each of the plurality of first word line contacts WLCA may have a tapered shape in which the horizontal width of the first word line contact WLCA increases from an upper side to a lower side thereof. For example, each of the plurality of first word line contacts WLCA may have a tapered shape in which the horizontal width of the first word line contact WLCA increases away from the first word line pad portion WLPA to which the first word line contact WLCA is connected. Each of the plurality of second word line contacts WLCB may have a tapered shape in which the horizontal width of the second word line contact WLCB increases from a lower side to an upper side thereof. For example, each of the plurality of second word line contacts WLCB may have a tapered shape in which the horizontal width of the second word line contact WLCB increases away from the second word line pad portion WLPB to which the second word line contact WLCB is connected.

The plurality of word lines WL may be electrically connected to a plurality of routing pads WRP through the plurality of word line contacts WLC. For example, each of the plurality of word lines WL may be electrically connected to a corresponding one of the plurality of routing pads WRP through a corresponding one of the plurality of word line contacts WLC. The plurality of routing pads WRP may include a plurality of first routing pads WRPA electrically connected to the plurality of first word lines WLA, and a plurality of second routing pads WRPB electrically connected to the plurality of second word lines WLB. The first routing pad WRPA and the second routing pad WRPB may be at the same vertical level. For example, upper and lower surfaces of the first routing pads WRPA may be coplanar with the upper and lower surfaces, respectively, of the second routing pads WRPB.

The first word line contact WLCA may connect between the first word line pad portion WLPA of the first word line WLA and the first routing pad WRPA. For example, an upper end of the first word line contact WLCA may be connected to the first word line pad portion WLPA of the first word line WLA, and a lower end of the first word line contact WLCA may be connected to the first routing pad WRPA. For example, the upper end of the first word line contact WLCA may contact the first word line pad portion WLPA of the first word line WLA, and the lower end of the first word line contact WLCA may contact the first routing pad WRPA. The second word line contact WLCB may connect between the second word line pad portion WLPB of the second word line WLB and a word line routing line WLRL. For example, an upper end of the second word line contact WLCB may be connected to the word line routing line WLRL, and a lower end of the second word line contact WLCB may be connected to the second word line pad portion WLPB of the second word line WLB. For example, the upper end of the second word line contact WLCB may contact the word line routing line WLRL, and the lower end of the second word line contact WLCB may contact the second word line pad portion WLPB of the second word line WLB. A word line routing via WLRV may be formed between the word line routing line WLRL and the second routing pad WRPB. For example, an upper end of the word line routing via WLRV may be connected to the word line routing line WLRL, and a lower end of the word line routing via WLRV may be connected to the second routing pad WRPB. For example, the upper end of the word line routing via WLRV may contact the word line routing line WLRL, and the lower end of the word line routing via WLRV may contact the second routing pad WRPB. The second word line pad portion WLPB of the second word line WLB may be electrically connected to the second routing pad WRPB through the second word line contact WLCB, the word line routing line WLRL, and the word line routing via WLRV.

Each of the plurality of word line routing vias WLRV may have a tapered shape in which the horizontal width of the word line routing via WLRV decreases from an upper side to a lower side thereof. For example, the plurality of word line routing vias WLRV may have tapered shapes in which the horizontal widths of the plurality of word line routing vias WLRV decrease toward the plurality of second routing pads WRPB. In some embodiments, the horizontal width of the uppermost end of each of the plurality of word line routing vias WLRV may be equal to or greater than the horizontal width of each of the plurality of second word line contacts WLCB.

The plurality of word line contacts WLC and the plurality of word line routing vias WLRV may be arranged in a matrix form arranged in lines in each of the first horizontal direction (X direction) and the second horizontal direction (Y direction) in a plan view. For example, in the first horizontal direction (X direction), the word line contacts WLC may be arranged in a line, and the word line routing vias WLRV may be arranged in a line. In the second horizontal direction (Y direction), the word line contacts WLC and the word line routing vias WLRV may be alternately arranged in a line. The plurality of word line routing lines WLRL connecting upper ends of the plurality of second word line contacts WLCB to upper ends of the plurality of word line routing vias WLRV may have horizontal shapes of linear bars extending in the second horizontal direction (Y direction).

The plurality of bit lines BL may extend lengthwise in the vertical direction (Z direction), and may be spaced apart from each other in each of the first horizontal direction (X direction) and the second horizontal direction (Y direction). The plurality of bit lines BL may include bit line columns, which are bit lines BL arranged spaced apart from each other in columns in the first horizontal direction (X direction), and the bit line columns may be arranged spaced apart from each other in the second horizontal direction (Y direction). Each of the bit line columns may be arranged along an extension line extending in the first horizontal direction (X direction) between two word line pad portions WLP adjacent to each other at the same vertical level in the second horizontal direction (Y direction). In some embodiments, one of the bit line columns and one pair of word lines WL may be repeatedly arranged in the second horizontal direction (Y direction) in a plan view.

The plurality of bit lines BL may include a plurality of first bit lines BLA and a plurality of second bit lines BLB. The plurality of first bit lines BLA may extend in the vertical direction (Z direction) through the plurality of first word lines WLA, and the plurality of second bit lines BLB may extend in the vertical direction (Z direction) through the plurality of second word lines WLB. In some embodiments, the first bit line BLA and the second bit line BLB that are aligned in the vertical direction (Z direction) may be spaced apart from each other. For example, the uppermost end of the first bit line BLA and the lowermost end of the second bit line BLB may be spaced apart from each other in the vertical direction (Z direction). Each of the plurality of first bit lines BLA may have a tapered shape in which the horizontal width of the first bit line BLA decreases from a lower side to an upper side thereof. For example, the plurality of first bit lines BLA may have tapered shapes in which the horizontal widths of the plurality of first bit lines BLA decrease toward the plurality of second bit lines BLB overlapping the plurality of first bit lines BLA in the vertical direction (Z direction). Each of the plurality of second bit lines BLB may have a tapered shape in which the horizontal width of the second bit line BLB decreases from an upper side to a lower side thereof. For example, the plurality of second bit lines BLB may have tapered shapes in which the horizontal widths of the plurality of second bit lines BLB decrease toward the plurality of first bit lines BLA overlapping the plurality of second bit lines BLB in the vertical direction (Z direction).

The semiconductor memory device 100 may include a plurality of memory cells MC each including a cell transistor CT and an information storage element SP. The cell transistor CT may include a semiconductor pattern 110. In some embodiments, the semiconductor pattern 110 may extend in the second horizontal direction (Y direction). The cell transistor CT may include a semiconductor pattern 110 having a source region and a drain region respectively located at two ends thereof in the second horizontal direction (Y direction). The cell transistor CT may be arranged between the word line WL and the bit line BL. The information storage element SP may be connected to the cell transistor CT. The information storage element SP may be a memory element capable of storing data. A gate of the cell transistor CT may be connected to the word line WL, and a source region of the cell transistor CT may be connected to the bit line BL. The information storage element SP may be connected to a drain region of the cell transistor CT.

The word line WL may be adjacent to the semiconductor pattern 110. In some embodiments, the word line WL may surround the semiconductor pattern 110. A gate dielectric film Gox may be arranged between the word line WL and the semiconductor pattern 110. For example, the gate dielectric film Gox may surround and contact the semiconductor pattern, and the word line WL may contact side surfaces of the gate dielectric film Gox. The word line WL and the gate dielectric film Gox may constitute a word line structure WLS. The semiconductor pattern 110 and the word line structure WLS may constitute a cell transistor CT. The plurality of semiconductor patterns 110 may include a plurality of first semiconductor patterns 110A and a plurality of second semiconductor patterns 110B. The first semiconductor pattern 110A may be adjacent to the first word line WLA, and the second semiconductor pattern 110B may be adjacent to the second word line WLB. The plurality of gate dielectric films Gox may include a plurality of first gate dielectric films GoxA and a plurality of second gate dielectric films GoxB. The first gate dielectric film GoxA may be arranged between the first word line WLA and the first semiconductor pattern 110A, and the second gate dielectric film GoxB may be arranged between the second word line WLB and the second semiconductor pattern 110B. The plurality of word line structures WLS may include a plurality of first word line structures WLSA and a plurality of second word line structures WLSB. The first word line WLA and the first gate dielectric film GoxA may constitute a first word line structure WLSA, and the second word line WLB and the second gate dielectric film GoxB may constitute a second word line structure WLSB.

In some embodiments, the source region and drain region of the cell transistor CT and the information storage element SP may be arranged in the second horizontal direction (Y direction) from the bit line BL connected to the source region of the cell transistor CT. The source regions and drain regions of the cell transistors CT, which are respectively connected to two bit lines BL adjacent to each other in the second horizontal direction (Y direction), and the information storage elements SP respectively connected to the cell transistors CT may be sequentially arranged in opposite directions. For example, the source region and drain region of the cell transistor CT, which is connected to one of the two bit lines BL adjacent to each other in the second horizontal direction (Y direction), and the information storage element SP connected to the cell transistor CT may be sequentially arranged in the second horizontal direction (Y direction), and the source region and drain region of the cell transistor CT, which is connected to the other bit line BL, and the information storage element SP connected to the cell transistor CT may be sequentially arranged in a direction opposite to the second horizontal direction (Y direction). For example, the plurality of bit lines BL may include a first bit line, a second bit line, a third bit line, and a fourth bit line that are sequentially arranged adjacent to each other in the second horizontal direction (Y direction), wherein a memory cell MC may not be arranged between the first bit line and the second bit line, two memory cells MC may be arranged between the second bit line and the third bit line at the same vertical level in the second horizontal direction (Y direction), and a memory cell MC may not be arranged between the third bit line and the fourth bit line.

A plurality of bit line contacts BLC may be connected to ends of the plurality of bit lines BL. The plurality of bit line contacts BLC may include a plurality of first bit line contacts BCA and a plurality of second bit line contacts BCB. The first bit line contact BCA may be connected to an end of the first bit line BLA opposite to the second bit line BLB. For example, the first bit line contact BCA may be connected to a lower end of the first bit line BLA. The second bit line contact BCB may be connected to an end of the second bit line BLB opposite to the first bit line BLA. For example, the second bit line contact BCB may be connected to an upper end of the second bit line BLB. A plurality of bit line connection patterns BLP may be connected to the plurality of bit line contacts BLC. For example, each of the plurality of bit line connection patterns BLP may contact a corresponding one of the plurality of bit line contacts BLC. The plurality of bit line connection patterns BLP may include a plurality of first bit line connection patterns BPA and a plurality of second bit line connection patterns BPB. The first bit line connection pattern BPA may be connected to a lower end of the first bit line contact BCA, and the second bit line connection pattern BPB may be connected to an upper end of the second bit line contact BCB. In some embodiments, the first bit line connection pattern BPA may be at the same vertical level as the first routing pad WRPA and the second routing pad WRPB, and the second bit line connection pattern BPB may be at the same vertical level as the word line routing line WLRL.

A plurality of insulation layers 150 may be arranged between the word lines WL aligned in the vertical direction (Z direction). For example, each of the plurality of insulation layers 150 may have an upper surface contacting a lower surface of a first one of the word lines WL, and a lower surface contacting an upper surface of a second one of the word lines WL. Among the plurality of insulation layers 150, the insulation layers 150 arranged between the uppermost first word lines WLA and the lowermost second word lines WLB may be referred to as middle insulation layers 150M. For example, the middle insulation layers 150M may have upper surfaces contacting lower surfaces of the lowermost second word lines WLB, and lower surfaces contacting upper surfaces of the uppermost first word lines WLA. Each of the middle insulation layers 150M among the plurality of insulation layers 150 may include the same material as each of the remaining insulation layers 150 excluding the middle insulation layers 150M. For example, the plurality of insulation layers 150 may include oxide, but are not limited thereto. The thickness of each of the middle insulation layers 150M among the plurality of insulation layers 150 may be equal to or greater than the thickness of each of the remaining insulation layers 150 excluding the middle insulation layers 150M.

An interlayer insulation layer ILD may surround the plurality of word lines WL, the plurality of word line contacts WLC, the plurality of bit lines BL, and the plurality of word line routing vias WLRV. The interlayer insulation layer ILD may contact the plurality of word lines WL, the plurality of word line contacts WLC, the plurality of bit lines BL, and the plurality of word line routing vias WLRV. The word line routing via WLRV may extend from the word line routing line WLRL to the second routing pad WRPB through the interlayer insulation layer ILD between the word lines WL, that is, between the word line pad portions WLP, adjacent to each other in the second horizontal direction (Y direction) in the pad region WPR. The interlayer insulation layer ILD may include oxide, but is not limited thereto. The interlayer insulation layer ILD may include a single layer, but is not limited thereto, and may have a multi-layer structure. In some embodiments, the plurality of insulation layers 150 may be portions of the interlayer insulation layer ILD. FIGS. 3C to 3E show that the first bit line connection pattern BPA, the first routing pad WRPA, and the second routing pad WRPB are located below a lower surface of the interlayer insulation layer ILD, and that the second bit line connection pattern BPB and the word line routing line WLRL are located on an upper surface of the interlayer insulation layer ILD, but embodiments are not limited thereto. In some embodiments, FIGS. 3C to 3E may show only a portion of the interlayer insulation layer ILD included in the semiconductor memory device 100. For example, the interlayer insulation layer ILD may be formed to cover the first bit line connection pattern BPA, the first routing pad WRPA, the second routing pad WRPB, the second bit line connection pattern BPB, and the word line routing line WLRL.

In the semiconductor memory device 100 according to the inventive concept, the plurality of first word line contacts WLCA extending downward from the plurality of first word line pad portions WLPA may be connected to the plurality of first word lines WLA included in the first word line stack WSA, and the plurality of second word line contacts WLCB extending upward from the plurality of second word line pad portions WLPB may be connected to the plurality of second word lines WLB included in the second word line stack WSB. Also, each of the plurality of word line routing vias WLRV connecting the plurality of second word line contacts WLCB to the plurality of second routing pads WRPB may be arranged between the word line pad portions WLP adjacent to each other in the second horizontal direction (Y direction), and thus, a separate space is not required to form a plurality of word line routing vias WLRV. Accordingly, the area in which the plurality of word line pad portions WLP are arranged in a plan view may be reduced, and thus, the degree of integration of the semiconductor memory device 100 may increase.

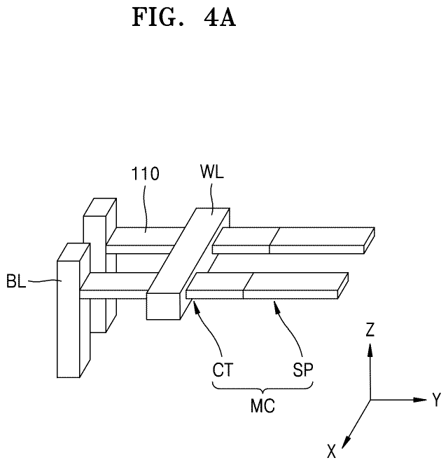

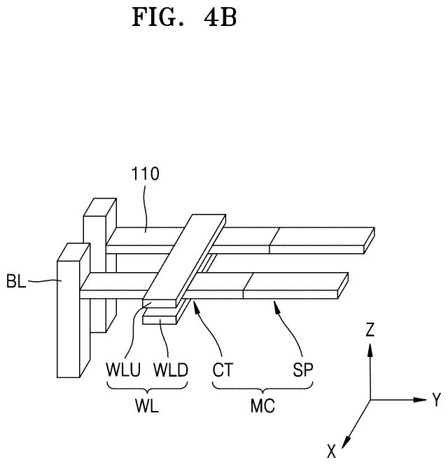

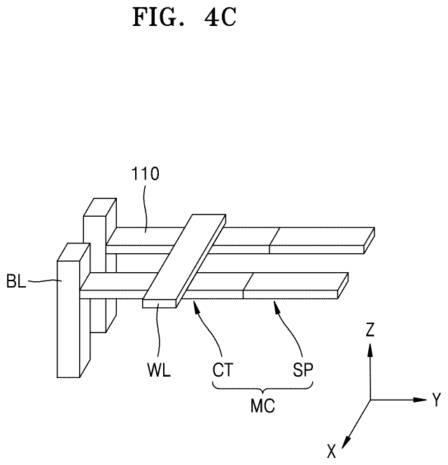

FIGS. 4A, 4B, and 4C are perspective views illustrating a memory cell MC included in a semiconductor memory device, according to example embodiments.

Referring to FIG. 4A, the memory cell MC may include a cell transistor CT and an information storage element SP. The cell transistor CT may be arranged between a word line WL and a bit line BL. The cell transistor CT may include a semiconductor pattern 110. An end of the semiconductor pattern 110 may be connected to the bit line BL, and the other end of the semiconductor pattern 110 may be connected to the information storage element SP. The word line WL may extend in a first horizontal direction (X direction), the bit line BL may extend in a vertical direction (Z direction), and the semiconductor pattern 110 may extend in a second horizontal direction (Y direction). A gate dielectric film Gox as shown in FIG. 3C may be arranged between the word line WL and the semiconductor pattern 110. In some embodiments, the semiconductor pattern 110 and the information storage element SP may be sequentially located in the second horizontal direction (Y direction) from the bit line BL.

In some embodiments, the word line WL may surround the semiconductor pattern 110. For example, the word line WL may have a gate-all-around shape that covers upper and lower surfaces and two side surfaces in the first horizontal direction (X direction) of a portion of the semiconductor pattern 110.

Referring to FIG. 4B, the memory cell MC may include a cell transistor CT and an information storage element SP. The cell transistor CT may be arranged between a word line WL and a bit line BL. The cell transistor CT may include a semiconductor pattern 110. A gate dielectric film Gox as shown in FIG. 3C may be arranged between the word line WL and the semiconductor pattern 110.

The word line WL may have a double gate shape that covers upper and lower surfaces of a portion of the semiconductor pattern 110. In some embodiments, the word line WL may include a lower word line WLD located below the semiconductor pattern 110 and an upper word line WLU located above the semiconductor pattern 110. For example, the upper word line WLU may cover the upper surface of the portion of the semiconductor pattern 110, and the lower word line WLD may cover the lower surface of the portion of the semiconductor pattern 110. For example, the upper word line WLU may contact the upper surface of the portion of the semiconductor pattern 110, and the lower word line WLD may contact the lower surface of the portion of the semiconductor pattern 110.

Referring to FIG. 4C, the memory cell MC may include a cell transistor CT and an information storage element SP. The cell transistor CT may be arranged between a word line WL and a bit line BL. The cell transistor CT may include a semiconductor pattern 110. A gate dielectric film Gox as shown in FIG. 3C may be arranged between the word line WL and the semiconductor pattern 110.

The word line WL may have a single gate shape that covers one of upper and lower surfaces of a portion of the semiconductor pattern 110. For example, the word line WL may cover the upper surface of the portion of the semiconductor pattern 110. For example, the word line WL may contact the upper surface of the portion of the semiconductor pattern 110. In some embodiments, the word line WL may cover the lower surface of the portion of the semiconductor pattern 110.

In the following description, descriptions redundant to those provided with reference to FIGS. 3A to 3E and FIGS. 4A to 4C may be omitted.

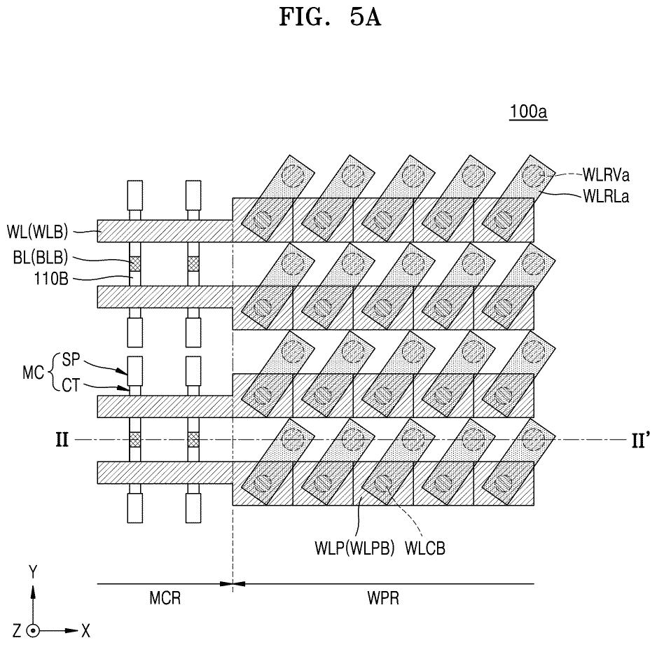

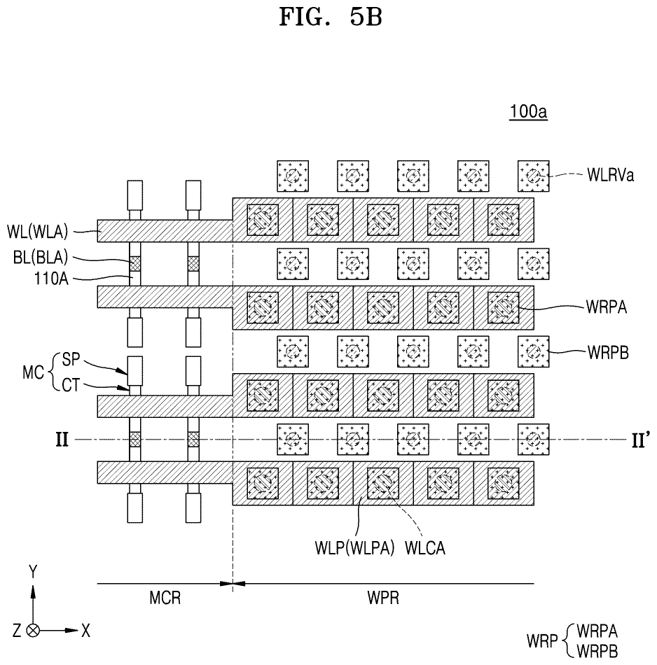

FIGS. 5A and 5B are plan layout views illustrating a semiconductor memory device 100a according to example embodiments. In detail, FIG. 5A is a top-down plan layout view of the semiconductor memory device 100a according to embodiments, and FIG. 5B is a bottom-up plan layout view of the semiconductor memory device 100a according to embodiments.

Referring to FIGS. 5A and 5B together, the semiconductor memory device 100a may include a plurality of word lines WL and a plurality of bit lines BL. The plurality of word lines WL may include a plurality of word line pad portions WLP. The plurality of word lines WL may include a plurality of first word lines WLA and a plurality of second word lines WLB. The plurality of word line pad portions WLP may include a plurality of first word line pad portions WLPA included in the plurality of first word lines WLA, and a plurality of second word line pad portions WLPB included in the plurality of second word lines WLB.

A first word line contact WLCA may be connected to the first word line pad portion WLPA, and a second word line contact WLCB may be connected to the second word line pad portion WLPB. A word line routing via WLRVa may be arranged between the word lines WL, that is, between the word line pad portions WLP, adjacent to each other in the second horizontal direction (Y direction) in the pad region WPR. A word line routing line WLRLa may be connected on each of the second word line contact WLCB and the word line routing via WLRVa. The word line routing line WLRLa may electrically connect the second word line contact WLCB to the word line routing via WLRVa.

A plurality of word line contacts WLC and a plurality of word line routing vias WLRVa may be arranged in a honeycomb shape in a zigzag manner with respect to the first horizontal direction (X direction) or the second horizontal direction (Y direction) in a plan view. For example, the word line contacts WLC may be arranged in a line and the word line routing vias WLRVa may be arranged in a line, in the first horizontal direction (X direction), and the word line contacts WLC and the word line routing vias WLRVa may be alternately arranged in a line in a diagonal direction with respect to the first horizontal direction (X direction) and the second horizontal direction (Y direction). The plurality of word line routing lines WLRLa connecting upper ends of the plurality of second word line contacts WLCB to upper ends of the plurality of word line routing vias WLRVa may have horizontal shapes of linear bars extending in the diagonal direction with respect to the first horizontal direction (X direction) and the second horizontal direction (Y direction).

In the semiconductor memory device 100a, the plurality of word line contacts WLC and the plurality of word line routing vias WLRVa may be arranged in a honeycomb shape, and thus, the degree of integration of the semiconductor memory device 100a may increase.

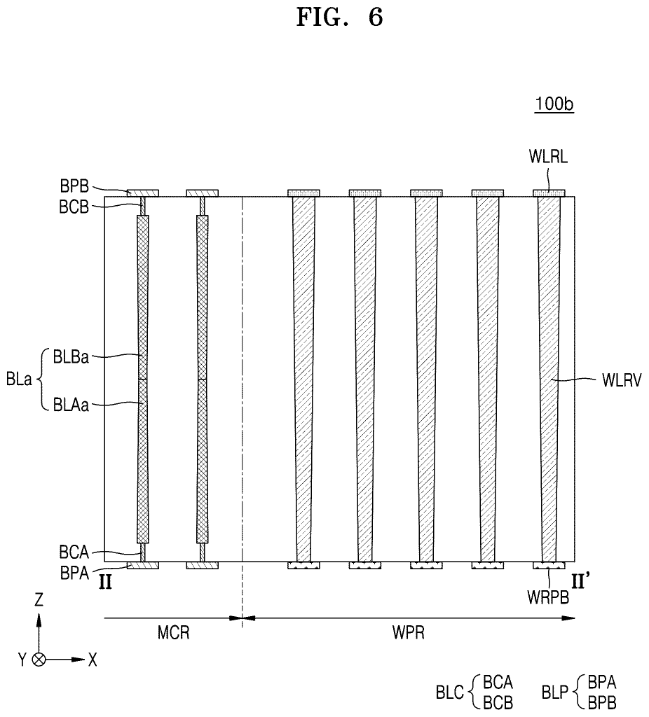

FIG. 6 is a cross-sectional view illustrating a semiconductor memory device 100b according to example embodiments. In detail, FIG. 6 is a cross-sectional view of the semiconductor memory device 100b, taken along a position corresponding to the line II-II′ of FIGS. 3A and 3B.

Referring to FIG. 6, the semiconductor memory device 100b may include a plurality of bit lines BLa and a plurality of word line routing vias WLRV. The plurality of bit lines BLa may include a plurality of first bit lines BLAa and a plurality of second bit lines BLBa. The plurality of first bit lines BLAa and the plurality of second bit lines BLBa may extend in the vertical direction (Z direction). Each of the plurality of first bit lines BLAa may have a tapered shape in which the horizontal width of the first bit line BLAa decreases from a lower side to an upper side thereof. Each of the plurality of second bit lines BLBa may have a tapered shape in which the horizontal width of the second bit line BLBa decreases from an upper side to a lower side thereof.

A plurality of bit line contacts BLC may be connected to ends of the plurality of bit lines BLa. For example, each of the plurality of bit line contacts BLC may contact the end of a corresponding one of the plurality of bit lines BLa. The plurality of bit line contacts BLC may include a plurality of first bit line contacts BCA and a plurality of second bit line contacts BCB. The first bit line contact BCA may be connected to an end of the first bit line BLAa opposite to the second bit line BLBa. For example, the first bit line contact BCA may be connected to a lower end of the first bit line BLAa. The second bit line contact BCB may be connected to an end of the second bit line BLBa opposite to the first bit line BLAa. For example, the second bit line contact BCB may be connected to an upper end of the second bit line BLBa. In some embodiments, the first bit line BLAa and the second bit line BLBa that are aligned in the vertical direction (Z direction) may be in contact with each other. For example, the other end of the first bit line BLAa, that is, an upper end thereof, and the other end of the second bit line BLBa, that is, a lower end thereof, may be in contact with each other.

A plurality of bit line connection patterns BLP may be connected to the plurality of bit line contacts BLC. For example, each of the plurality of bit line connection patterns BLP may contact a corresponding one of the plurality of bit line contacts BLC. The plurality of bit line connection patterns BLP may include a plurality of first bit line connection patterns BPA and a plurality of second bit line connection patterns BPB. The first bit line connection pattern BPA may be connected to a lower end of the first bit line contact BCA, and the second bit line connection pattern BPB may be connected to an upper end of the second bit line contact BCB.

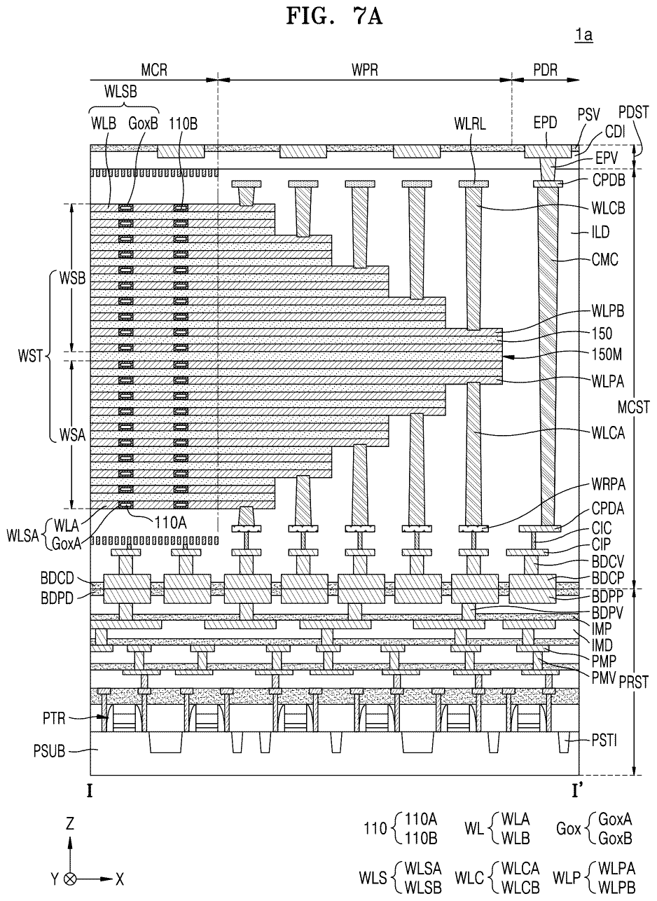

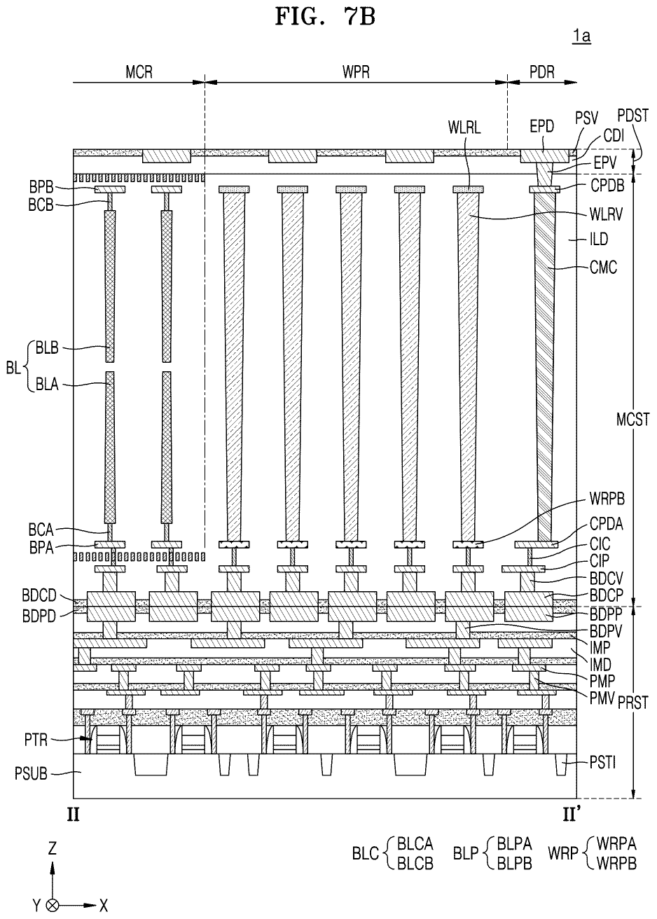

FIGS. 7A and 7B are cross-sectional views illustrating a semiconductor memory device 1a according to example embodiments. In detail, FIG. 7A is a cross-sectional view of the semiconductor memory device 1a, taken along a position corresponding to the line I-I′ of FIGS. 3A and 3B, and FIG. 7B is a cross-sectional view of the semiconductor memory device 1a, taken along a position corresponding to the line II-II′ of FIGS. 3A and 3B.

Referring to FIGS. 7A and 7B together, the semiconductor memory device 1a may have a memory cell region MCR, a pad region WPR, and an external connection region PDR that are arranged in the first horizontal direction (X direction). The semiconductor memory device 1a may include a peripheral circuit structure PRST, a memory cell structure MCST above the peripheral circuit structure PRST, and a pad structure PDST above the memory cell structure MCST. The peripheral circuit structure PRST, the memory cell structure MCST, and the pad structure PDST may be arbitrarily distinguished from each other based on convenience of description and functional differences, and thus, the distinction between these structures may not be clear.

The peripheral circuit structure PRST may include a peripheral circuit substrate PSUB and a plurality of peripheral circuit transistors PTR. The plurality of peripheral circuit transistors PTR may be arranged on upper surfaces of portions of the peripheral circuit substrate PSUB that are defined by a peripheral circuit device isolation film PSTI. The plurality of peripheral circuit transistors PTR may be configured to transmit signals and/or power to a plurality of memory cells included in the memory cell structure MCST. For example, the plurality of peripheral circuit transistors PTR may constitute various circuits, such as a command decoder, a control logic, an address buffer, a row decoder, a column decoder, a sense amplifier, and a data input/output circuit. FIGS. 7A and 7B show that the peripheral circuit transistor PTR is a planar transistor, but embodiments are not limited thereto. For example, the peripheral circuit transistor PTR may be a fin field-effect transistor (FinFET) or a vertical gate transistor. The plurality of peripheral circuit transistors PTR may be arranged on an upper surface of the peripheral circuit substrate PSUB to face the memory cell structure MCST. The upper surface of the peripheral circuit substrate PSUB may be an active surface of the peripheral circuit substrate PSUB. For example, the semiconductor memory device 1a may have a cell-on-periphery (CoP)-face structure in which the memory cell structure MCST is arranged above the peripheral circuit structure PRST, and the active surface of the peripheral circuit substrate PSUB and the plurality of peripheral circuit transistors PTR face the memory cell structure MCST.

The peripheral circuit structure PRST may include a plurality of peripheral circuit connection patterns PMP above the peripheral circuit substrate PSUB, a plurality of peripheral circuit connection vias PMV connected to the plurality of peripheral circuit connection patterns PMP, and a peripheral circuit wiring insulation layer IMD that surrounds the plurality of peripheral circuit connection patterns PMP and the plurality of peripheral circuit connection vias PMV and covers the peripheral circuit substrate PSUB. When the plurality of peripheral circuit connection patterns PMP are embedded in the peripheral circuit wiring insulation layer IMD, the peripheral circuit structure PRST may further include a peripheral circuit wiring protection layer IMP covering the plurality of peripheral circuit connection patterns PMP and the peripheral circuit wiring insulation layer IMD. The peripheral circuit wiring insulation layer IMD may include oxide, and the peripheral circuit wiring protection layer IMP may include nitride. The lowermost peripheral circuit connection via PMV among the plurality of peripheral circuit connection vias PMV may be connected to the peripheral circuit substrate PSUB and/or the plurality of peripheral circuit transistors PTR.

The peripheral circuit structure PRST may further include a peripheral circuit bonding pad BDPP arranged above the peripheral circuit wiring insulation layer IMD, a peripheral circuit bonding insulation layer BDPD surrounding the peripheral circuit bonding pad BDPP, and a peripheral circuit bonding via BDPV connecting the peripheral circuit bonding pad BDPP to the peripheral circuit connection pattern PMP. The peripheral circuit bonding via BDPV may penetrate the peripheral circuit wiring insulation layer IMD and/or the peripheral circuit wiring protection layer IMP to connect the peripheral circuit bonding pad BDPP to the peripheral circuit connection pattern PMP. An upper surface of the peripheral circuit bonding pad BDPP may be coplanar with an upper surface of the peripheral circuit bonding insulation layer BDPD.

The memory cell structure MCST may include a plurality of word lines WL constituting a word line stack WST, a plurality of bit lines BL, a plurality of word line contacts WLC, a plurality of word line routing lines WLRL, a plurality of word line routing vias WLRV, a plurality of bit line contacts BLC, a plurality of bit line connection patterns BLP, and a plurality of routing pads WRP.

A plurality of cell connection patterns CIP, and a plurality of cell connection contacts CIC connecting the plurality of bit line connection patterns BLP and/or the plurality of routing pads WRP to the plurality of cell connection patterns CIP may be arranged below the plurality of bit line connection patterns BLP and the plurality of routing pads WRP. An interlayer insulation layer ILD may surround the plurality of cell connection patterns CIP and the plurality of cell connection contacts CIC.

The memory cell structure MCST may further include a cell bonding pad BDCP arranged below the interlayer insulation layer ILD, a cell bonding insulation layer BDCD surrounding the cell bonding pad BDCP, and a cell bonding via BDCV connecting the cell bonding pad BDCP to the bit line connection pattern BLP. The cell bonding via BDCV may penetrate the interlayer insulation layer ILD to connect the cell bonding pad BDCP to the cell connection pattern CIP. A lower surface of the cell bonding pad BDCP may be coplanar with a lower surface of the cell bonding insulation layer BDCD.

The memory cell structure MCST may be bonded onto the peripheral circuit structure PRST through the cell bonding pad BDCP, the peripheral circuit bonding pad BDPP, the cell bonding insulation layer BDCD, and the peripheral circuit bonding insulation layer BDPD. For example, the cell bonding insulation layer BDCD and the peripheral circuit bonding insulation layer BDPD may be bonded together by covalent bonding, and the cell bonding pad BDCP and the peripheral circuit bonding pad BDPP may face each other, expand due to heat, come into contact with each other, and be bonded together by diffusion bonding to form a single body through diffusion of metal atoms included therein. The memory cell structure MCST and the peripheral circuit structure PRST may be bonded together by using a hybrid bonding method. The cell bonding pad BDCP and the peripheral circuit bonding pad BDPP may each include a material including copper (Cu). The cell bonding insulation layer BDCD and the peripheral circuit bonding insulation layer BDPD may each include silicon oxide or silicon carbon nitride (SiCN).

The memory cell structure MCST may further include a cell wiring contact CMC extending in the vertical direction (Z direction) through the interlayer insulation layer ILD. The cell wiring contact CMC may connect between a lower cell-peripheral circuit connection pad CPDA and an upper cell-peripheral circuit connection pad CPDB. The cell wiring contact CMC, the lower cell-peripheral circuit connection pad CPDA, and the upper cell-peripheral circuit connection pad CPDB may be located in the external connection region PDR. In some embodiments, the lower cell-peripheral circuit connection pad CPDA may be at the same vertical level as the first routing pad WRPA and the second routing pad WRPB, and the upper cell-peripheral circuit connection pad CPDB may be at the same vertical level as the word line routing line WLRL. The lower cell-peripheral circuit connection pad CPDA may be electrically connected to the peripheral circuit structure PRST through one of the plurality of cell connection contacts CIC.

In some embodiments, the cell wiring contact CMC and the word line routing via WLRV may be formed together. For example, upper and lower ends of the cell wiring contact CMC may be at the same vertical level as upper and lower ends of the word line routing via WLRV, respectively. For example, the cell wiring contact CMC may have a tapered shape in which the horizontal width of the cell wiring contact CMC decreases from an upper side to a lower side thereof.

The pad structure PDST may include an external connection pad EPD above the memory cell structure MCST, an external connection via EPV connecting the external connection pad EPD to the upper cell-peripheral circuit connection pad CPDB, and a cover insulation layer CDI surrounding the external connection pad EPD and the external connection via EPV. In some embodiments, the external connection via EPV may be formed to extend into the interlayer insulation layer ILD of the memory cell structure MCST. In some embodiments, a protective insulation layer PSV may be arranged above the cover insulation layer CDI. At least a portion of an upper surface of the external connection pad EPD may be exposed without being covered by the protective insulation layer PSV. The cover insulation layer CDI may include oxide, and the protective insulation layer PSV may include nitride.

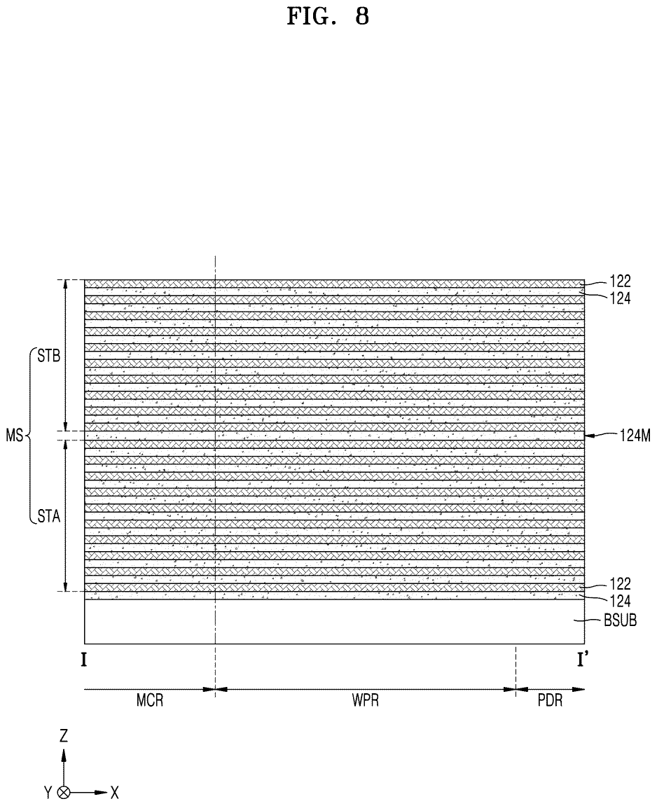

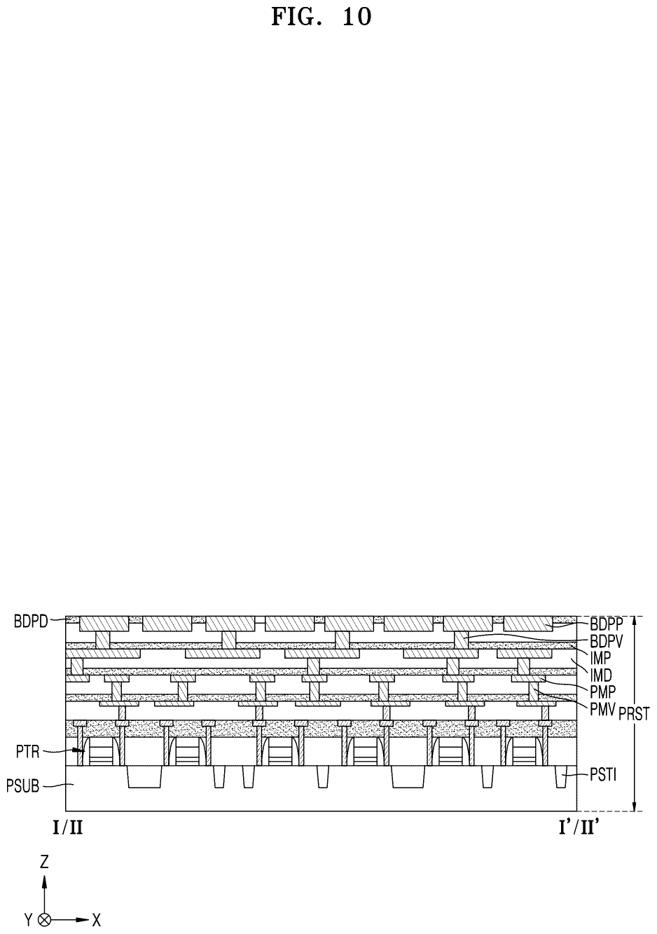

FIGS. 8, 9A, 9B, 10, 11A, 11B, 12A, and 12B are cross-sectional views illustrating a method of manufacturing a semiconductor memory device, according to example embodiments. In detail, FIGS. 8 and 10 are cross-sectional views taken along positions corresponding to the lines I-I′ and II-II′ of FIGS. 3A and 3B, FIGS. 9A, 11A, and 12A are cross-sectional views taken along a position corresponding to the line I-I′ of FIGS. 3A and 3B, and FIGS. 9B, 11B, and 12B are cross-sectional views taken along a position corresponding to the line II-II′ of FIGS. 3A and 3B.

Referring to FIG. 8, a plurality of sacrificial layers 124 and a plurality of semiconductor layers 122 may be alternately stacked one by one above a base substrate BSUB to form a stacked structure MS. The base substrate BSUB may include a semiconductor material. The plurality of sacrificial layers 124 and the plurality of semiconductor layers 122 may each include a semiconductor material. The sacrificial layer 124 may include a semiconductor material having an etch selectivity with respect to the semiconductor layer 122. For example, the semiconductor layer 122 may be formed of or include Si, and the sacrificial layer 124 may be formed of or include SiGe or SiGeC.

The stacked structure MS may include a first stacked structure STA and a second stacked structure STB above the first stacked structure STA. The plurality of sacrificial layers 124 may include a middle sacrificial layer 124M. The middle sacrificial layer 124M may be a sacrificial layer 124 arranged between the first stacked structure STA and the second stacked structure STB, among the plurality of sacrificial layers 124. In some embodiments, the types of elements included in respective materials constituting the plurality of sacrificial layers 124 may be the same, but the ratio of elements included in the material constituting the middle sacrificial layer 124M may be different from the ratio of elements included in the material constituting the remaining sacrificial layers 124. For example, when the plurality of sacrificial layers 124 include SiGe, the ratio of Si to Ge in the material constituting the middle sacrificial layer 124M may be different from the ratio of Si to Ge in the material constituting the remaining sacrificial layers 124. In some embodiments, the thickness in the vertical direction (Z direction) of the middle sacrificial layer 124M may be greater than each of the thicknesses in the vertical direction (Z direction) of the remaining sacrificial layers 124.

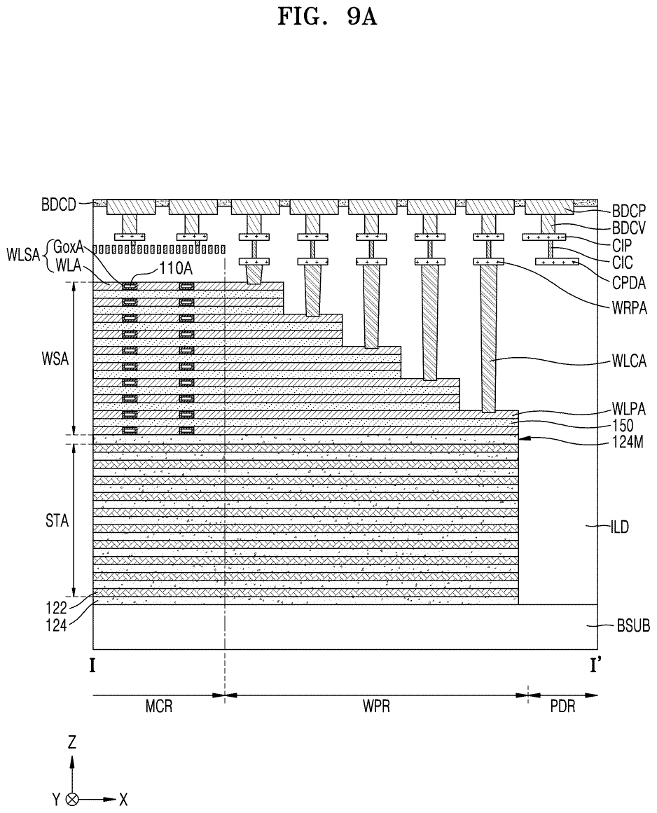

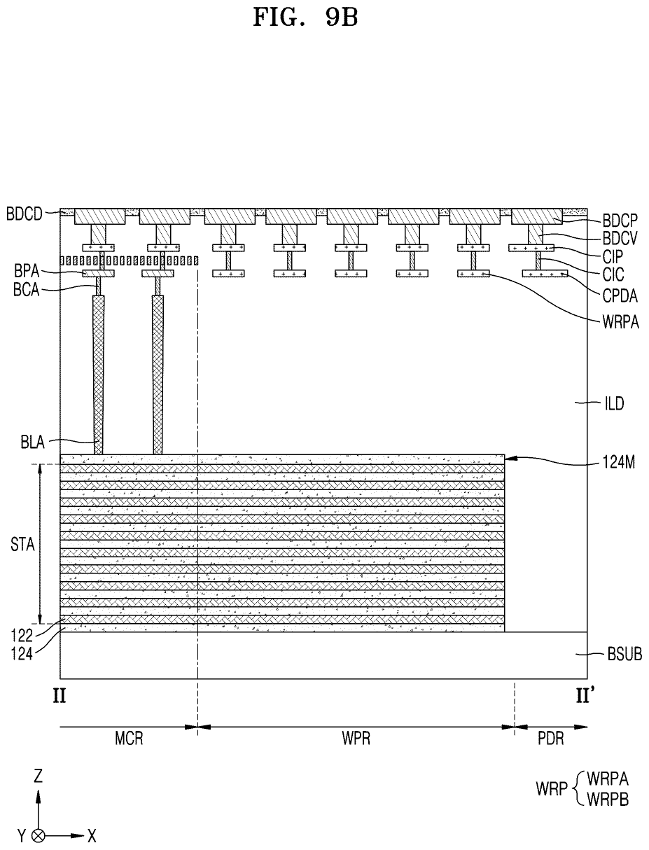

Referring to FIGS. 8, 9A, and 9B together, portions of the semiconductor layers 122 and the sacrificial layers 124 included in the second stacked structure STB may be removed to form a staircase structure in the pad region WPR, and the sacrificial layers 124 and at least portions of the semiconductor layers 122 may be removed to form a plurality of first word lines WLA, a plurality of first bit lines BLA, a plurality of first semiconductor patterns 110A, a plurality of first gate dielectric films GoxA, an interlayer insulation layer ILD, insulation layers 150, a plurality of first bit line contacts BCA, a plurality of first bit line connection patterns BPA, a plurality of first word line contacts WLCA, a plurality of routing pads WRP including a plurality of first routing pads WRPA and a plurality of second routing pads WRPB, a lower cell-peripheral circuit connection pad CPDA, a plurality of cell connection contacts CIC, a plurality of cell connection patterns CIP, a cell bonding via BDCV, a cell bonding pad BDCP, and a cell bonding insulation layer BDCD. The plurality of first word lines WLA may constitute a first word line stack WSA. In some embodiments, the middle sacrificial layer 124M may function as an etch stop film in an etching process for forming a plurality of first bit lines BLA.

Referring to FIG. 10, a peripheral circuit structure PRST including a peripheral circuit substrate PSUB, a plurality of peripheral circuit transistors PTR, a plurality of peripheral circuit connection patterns PMP, a plurality of peripheral circuit connection vias PMV, a peripheral circuit wiring insulation layer IMD, a peripheral circuit wiring protection layer IMP, a peripheral circuit bonding via BDPV, a peripheral circuit bonding pad BDPP, and a peripheral circuit bonding insulation layer BDPD may be formed.

Referring to FIGS. 9A, 9B, 10, 11A, and 11B together, the result of FIGS. 9A and 9B may be turned over and attached onto the result of FIG. 10, such that the cell bonding pad BDCP and the peripheral circuit bonding pad BDPP are bonded together, and the cell bonding insulation layer BDCD and the peripheral circuit bonding insulation layer BDPD are bonded together.

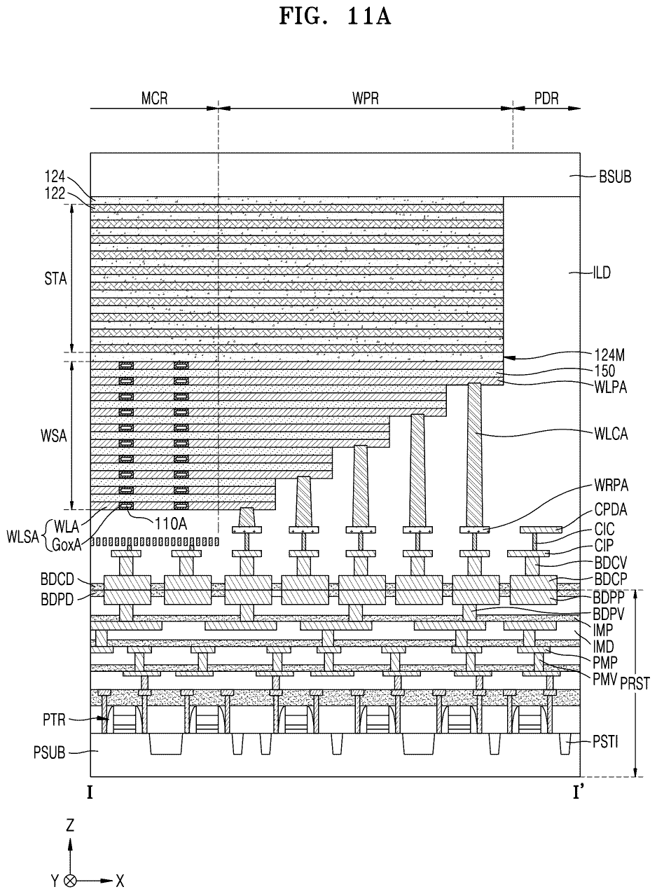

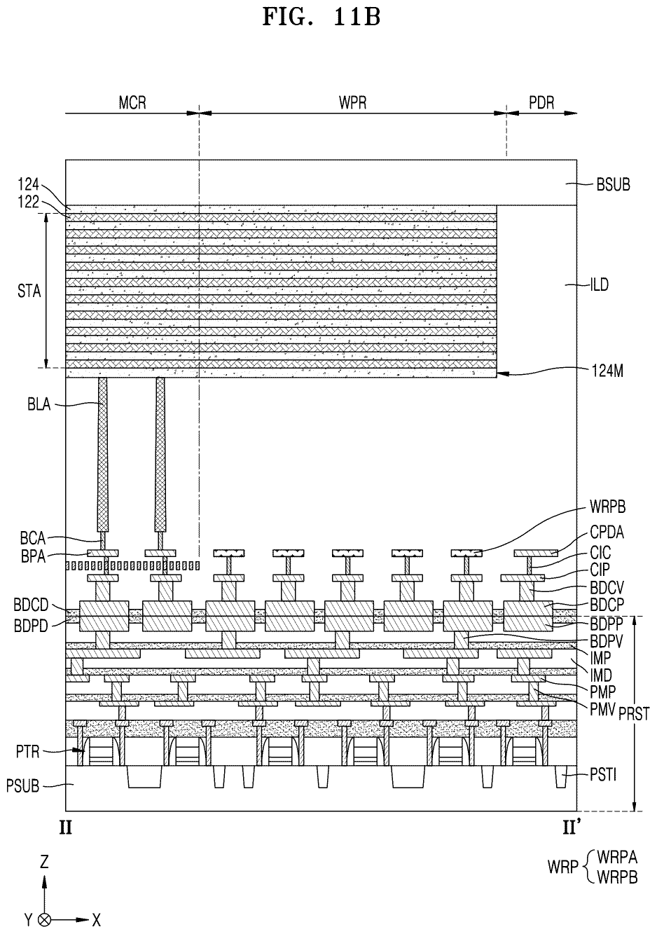

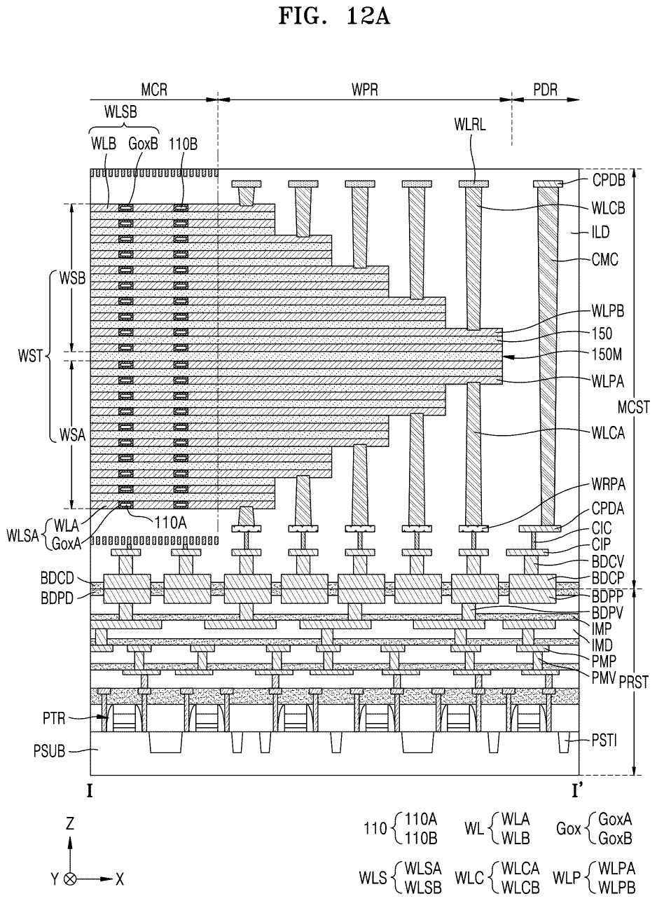

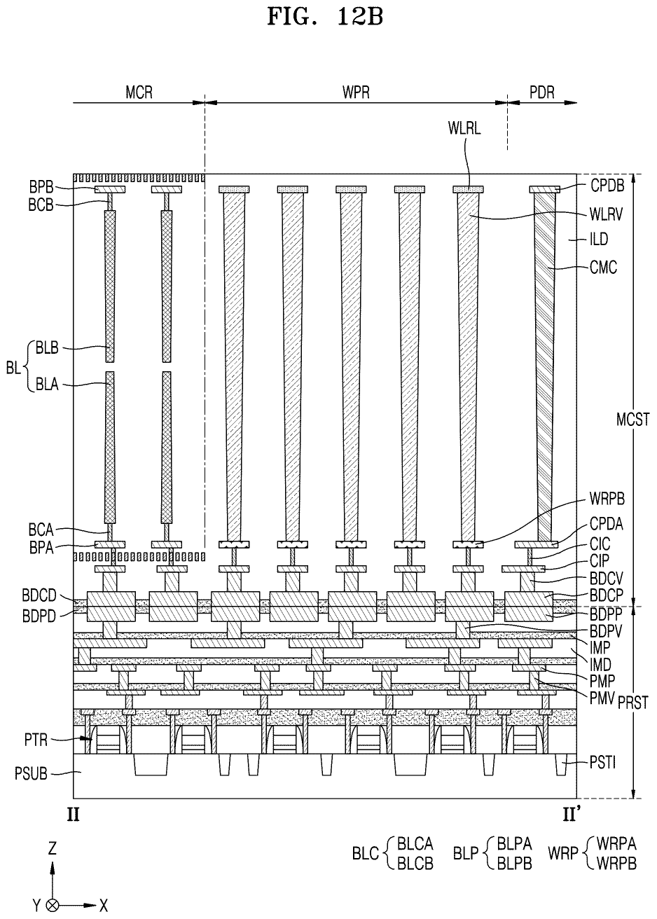

Referring to FIGS. 11A, 11B, 12A, and 12B together, the base substrate BSUB may be removed, portions of the semiconductor layers 122 and the sacrificial layers 124 included in the first stacked structure STA may be removed to form a staircase structure in the pad region WPR, and the sacrificial layers 124 and at least portions of the semiconductor layers 122 may be removed to form a plurality of second word lines WLB, a plurality of second bit lines BLB, a plurality of second semiconductor patterns 110B, a plurality of second gate dielectric films GoxB, an interlayer insulation layer ILD, insulation layers 150, a plurality of second bit line contacts BCB, a plurality of second bit line connection patterns BPB, a plurality of second word line contacts WLCB, a plurality of word line routing vias WLRV, a cell wiring contact CMC, a plurality of word line routing lines WLRL, and an upper cell-peripheral circuit connection pad CPDB. The plurality of second word lines WLB may constitute a second word line stack WSB. In some embodiments, the middle sacrificial layer 124M may function as an etch stop film in an etching process for forming a plurality of second bit lines BLB, and a middle insulation layer 150M may be formed at a location where the middle sacrificial layer 124M has been removed.

Thereafter, a pad structure PDST including an external connection via EPV, an external connection pad EPD, a cover insulation layer CDI, and a protective insulation layer PSV as shown in FIGS. 7A and 7B may be formed above the memory cell structure MCST, thereby forming a semiconductor memory device 1a.

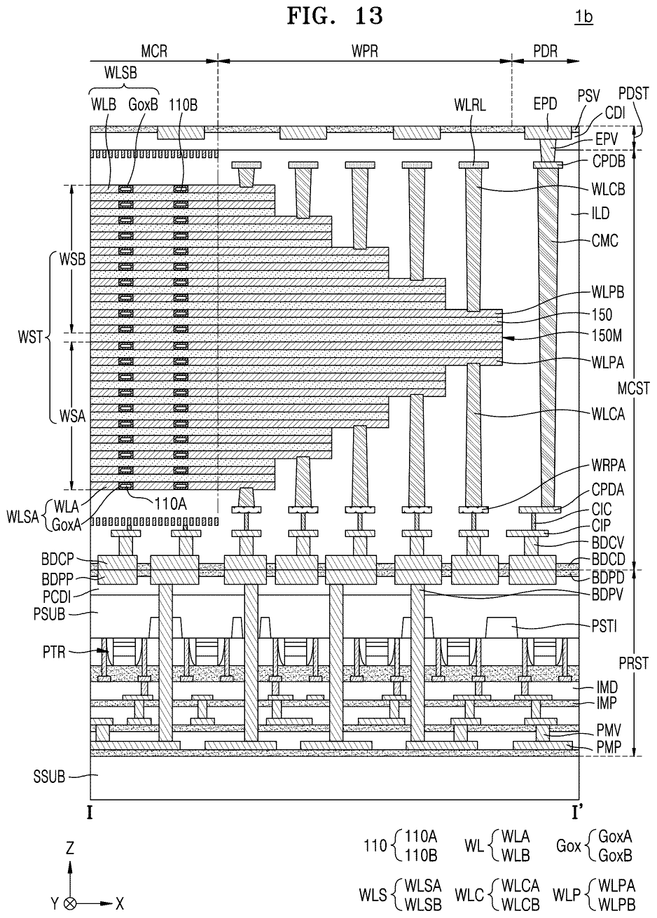

FIG. 13 is a cross-sectional view illustrating a semiconductor memory device 1b according to example embodiments. In detail, FIG. 13 is a cross-sectional view of the semiconductor memory device 1b, taken along a position corresponding to the line I-I′ of FIGS. 3A and 3B.

Referring to FIG. 13, the semiconductor memory device 1b may have a memory cell region MCR, a pad region WPR, and an external connection region PDR that are arranged in the first horizontal direction (X direction). The semiconductor memory device 1b may include a peripheral circuit structure PRST, a memory cell structure MCST above the peripheral circuit structure PRST, and a pad structure PDST above the memory cell structure MCST. The memory cell structure MCST and the pad structure PDST included in the semiconductor memory device 1b may be substantially the same as the memory cell structure MCST and the pad structure PDST included in the semiconductor memory device 1a shown in FIGS. 7A and 7B, and thus, redundant descriptions thereof may be omitted.

The peripheral circuit structure PRST may include a peripheral circuit substrate PSUB and a plurality of peripheral circuit transistors PTR. The plurality of peripheral circuit transistors PTR may be arranged on lower surfaces of portions of the peripheral circuit substrate PSUB that are defined by a peripheral circuit device isolation film PSTI. The plurality of peripheral circuit transistors PTR may be arranged on a lower surface of the peripheral circuit substrate PSUB opposite to the memory cell structure MCST. The lower surface of the peripheral circuit substrate PSUB may be an active surface of the peripheral circuit substrate PSUB. For example, the semiconductor memory device 1b may have a CoP-back structure in which the memory cell structure MCST is arranged above the peripheral circuit structure PRST, an upper surface of the peripheral circuit substrate PSUB, which is an inactive surface of the peripheral circuit substrate PSUB, faces the memory cell structure MCST, and the plurality of peripheral circuit transistors PTR face away from the memory cell structure MCST.

The peripheral circuit structure PRST may include a plurality of peripheral circuit connection patterns PMP and a plurality of peripheral circuit connection vias PMV that are arranged below the peripheral circuit substrate PSUB, and a peripheral circuit wiring insulation layer IMD that surrounds the plurality of peripheral circuit connection patterns PMP and the plurality of peripheral circuit connection vias PMV and covers the lower surface of the peripheral circuit substrate PSUB. When the plurality of peripheral circuit connection patterns PMP are embedded in the peripheral circuit wiring insulation layer IMD, the peripheral circuit structure PRST may further include a peripheral circuit wiring protection layer IMP covering lower surfaces of the plurality of peripheral circuit connection patterns PMP and a lower surface of the peripheral circuit wiring insulation layer IMD.

The peripheral circuit structure PRST may further include a peripheral circuit cover insulation layer PCDI covering the inactive surface, that is, the upper surface, of the peripheral circuit substrate PSUB, a peripheral circuit bonding pad BDPP arranged above the peripheral circuit cover insulation layer PCDI, a peripheral circuit bonding insulation layer BDPD surrounding the peripheral circuit bonding pad BDPP, and a peripheral circuit bonding via BDPV connecting the peripheral circuit bonding pad BDPP to the peripheral circuit connection pattern PMP. The peripheral circuit bonding via BDPV may penetrate the peripheral circuit cover insulation layer PCDI, the peripheral circuit substrate PSUB, the peripheral circuit wiring insulation layer IMD, and/or the peripheral circuit wiring protection layer IMP to connect the peripheral circuit bonding pad BDPP to the peripheral circuit connection pattern PMP. An upper surface of the peripheral circuit bonding pad BDPP may be coplanar with an upper surface of the peripheral circuit bonding insulation layer BDPD.

The memory cell structure MCST may be bonded onto the peripheral circuit structure PRST through the cell bonding pad BDCP, the peripheral circuit bonding pad BDPP, the cell bonding insulation layer BDCD, and the peripheral circuit bonding insulation layer BDPD.

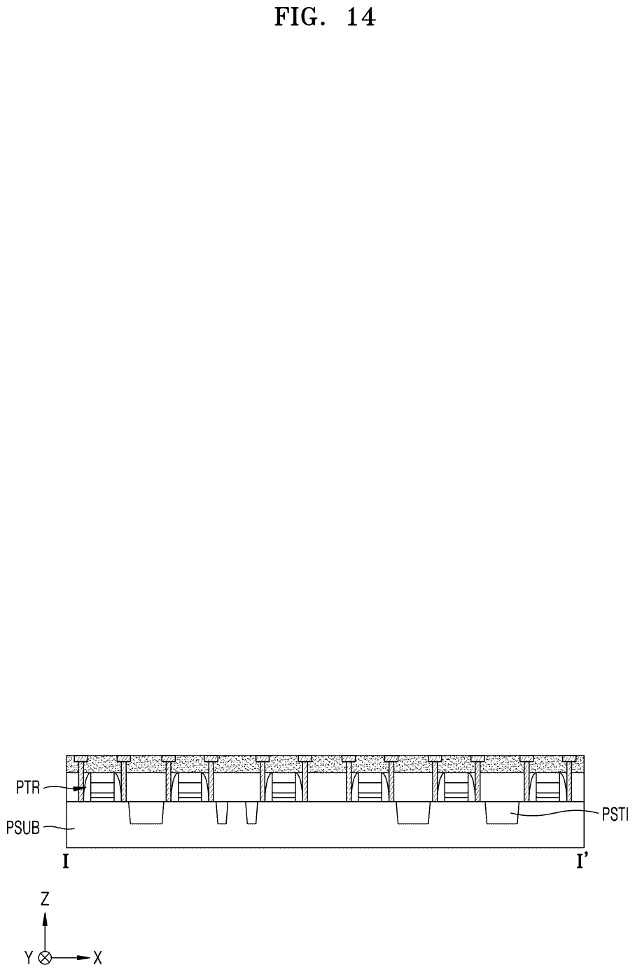

FIGS. 14 to 18 are cross-sectional views illustrating a method of manufacturing a semiconductor memory device, according to embodiments. In detail, FIGS. 14 to 18 are cross-sectional views taken along a position corresponding to the line I-I′ of FIGS. 3A and 3B.

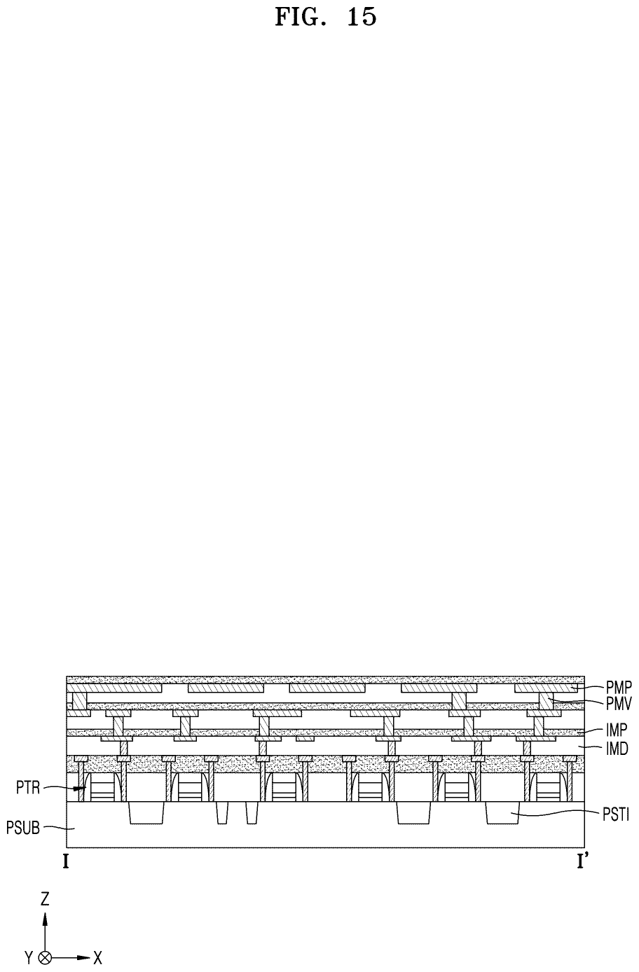

Referring to FIGS. 14 and 15 together, a plurality of peripheral circuit transistors PTR may be formed above a peripheral circuit substrate PSUB, and a plurality of peripheral circuit connection patterns PMP, a plurality of peripheral circuit connection vias PMV, a peripheral circuit wiring insulation layer IMD, and a peripheral circuit wiring protection layer IMP may be formed above the peripheral circuit substrate PSUB and the plurality of peripheral circuit transistors PTR.

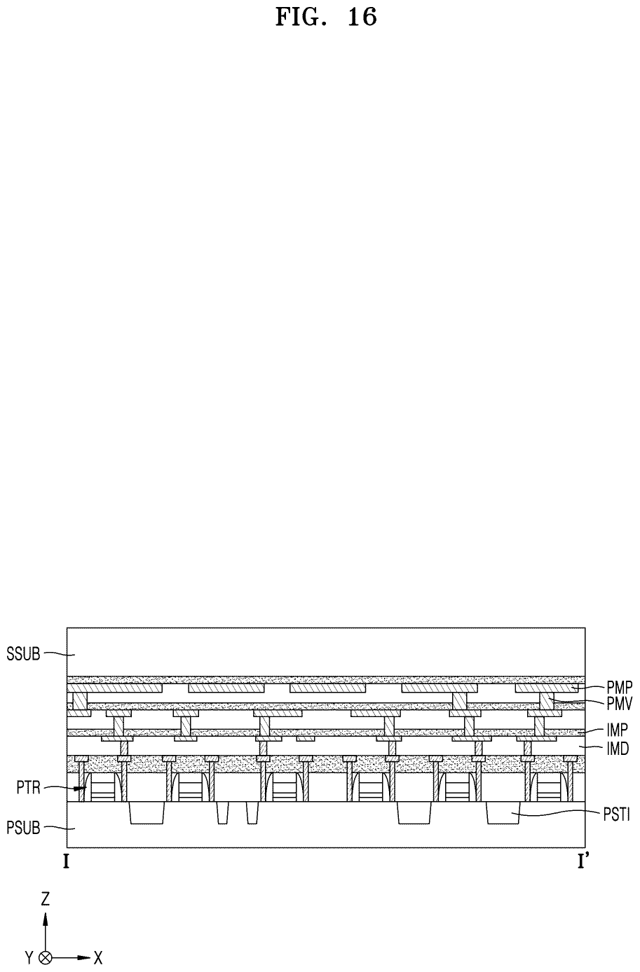

Referring to FIG. 16, a support substrate SSUB may be attached onto the result of FIG. 15, for example, onto the peripheral circuit wiring protection layer IMP.

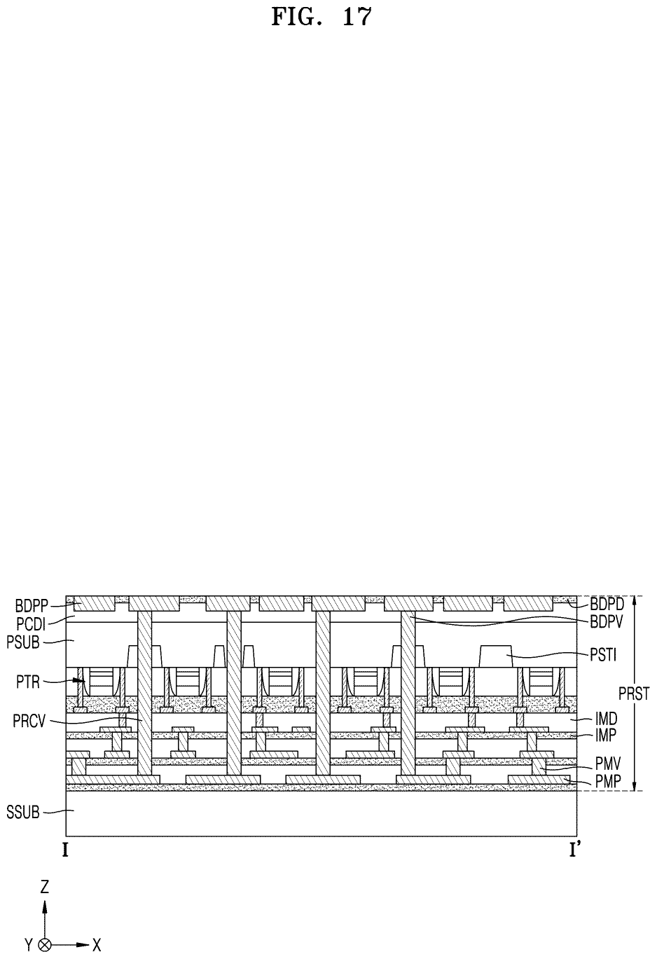

Referring to FIG. 17, after the result of FIG. 16 is turned over such that the support substrate SSUB faces downward and the peripheral circuit substrate PSUB faces upward, a peripheral circuit cover insulation layer PCDI covering an inactive surface, that is, an upper surface, of the peripheral circuit substrate PSUB, a peripheral circuit bonding pad BDPP arranged above the peripheral circuit cover insulation layer PCDI, a peripheral circuit bonding insulation layer BDPD surrounding the peripheral circuit bonding pad BDPP, and a peripheral circuit bonding via BDPV connecting the peripheral circuit bonding pad BDPP to the peripheral circuit connection pattern PMP may be formed, thereby forming a peripheral circuit structure PRST.

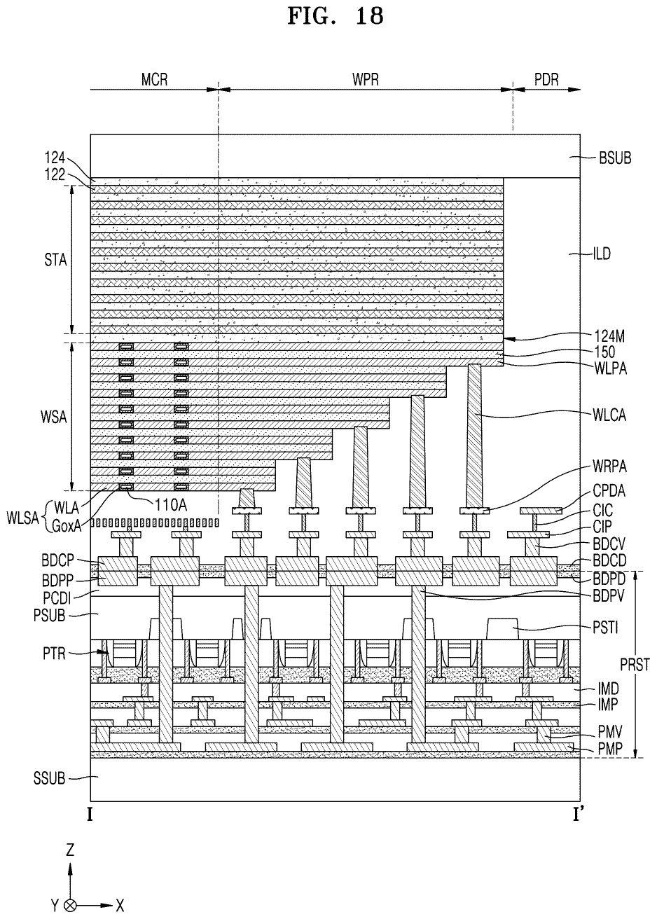

Referring to FIG. 18, the result of FIGS. 9A and 9B may be turned over and attached onto the result of FIG. 17, such that the cell bonding pad BDCP and the peripheral circuit bonding pad BDPP are bonded together, and the cell bonding insulation layer BDCD and the peripheral circuit bonding insulation layer BDPD are bonded together. Thereafter, with reference to FIGS. 12A and 12B, a semiconductor memory device 1b may be formed.

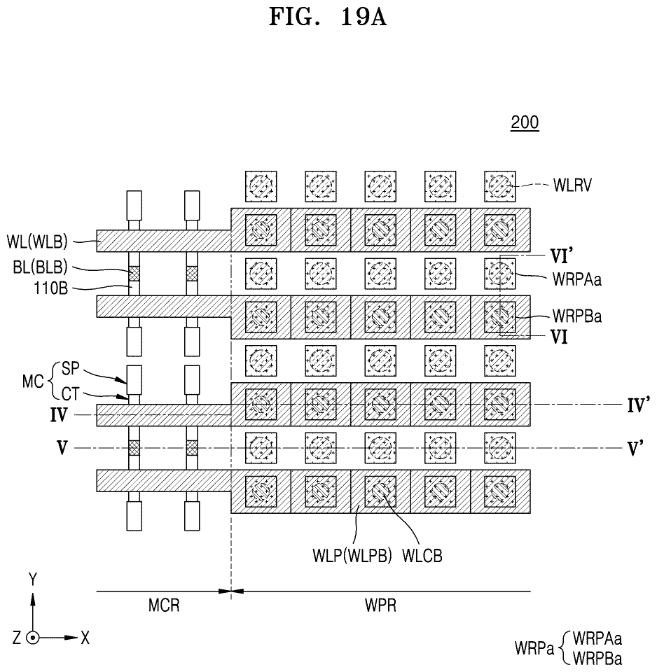

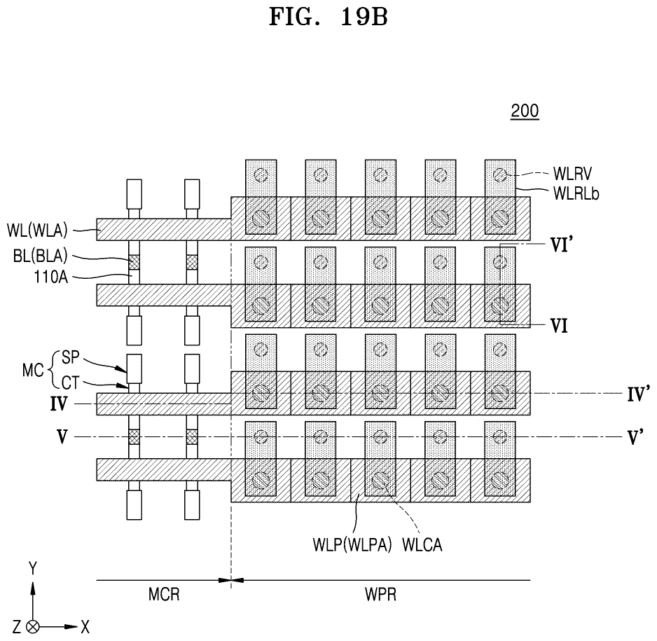

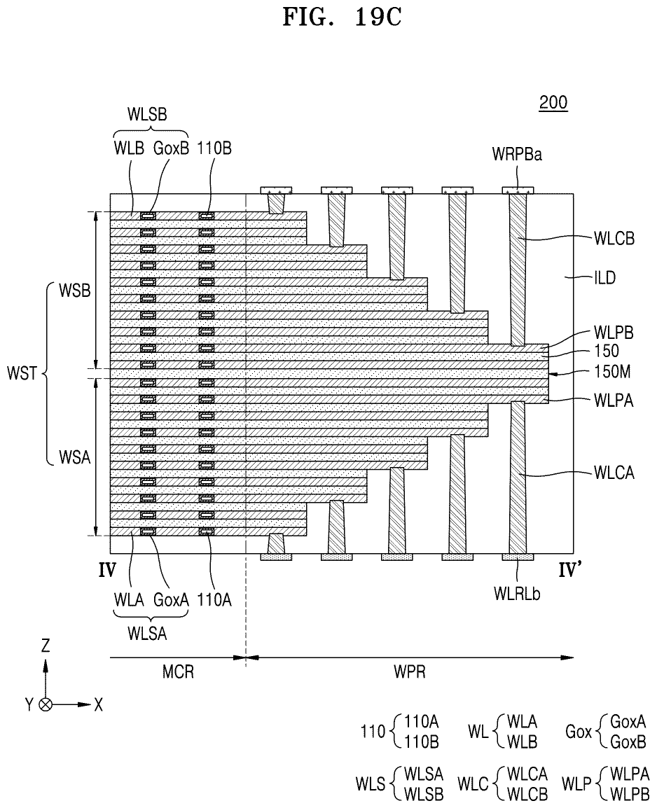

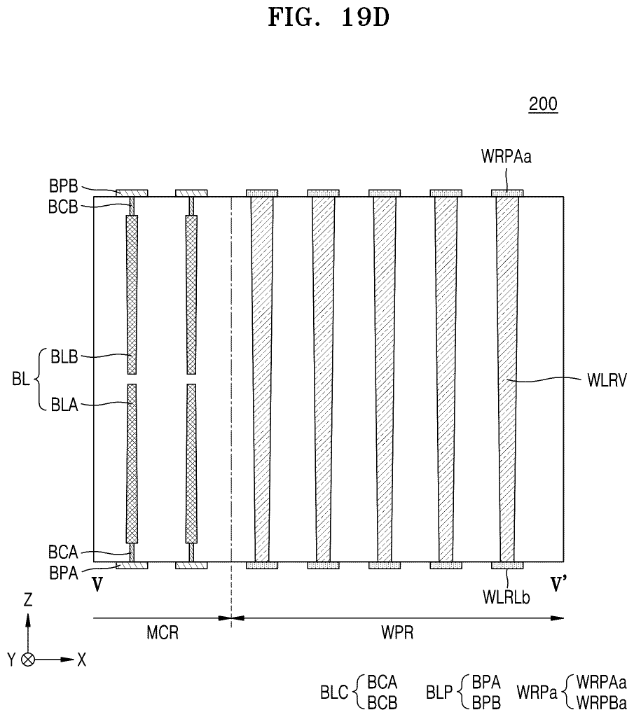

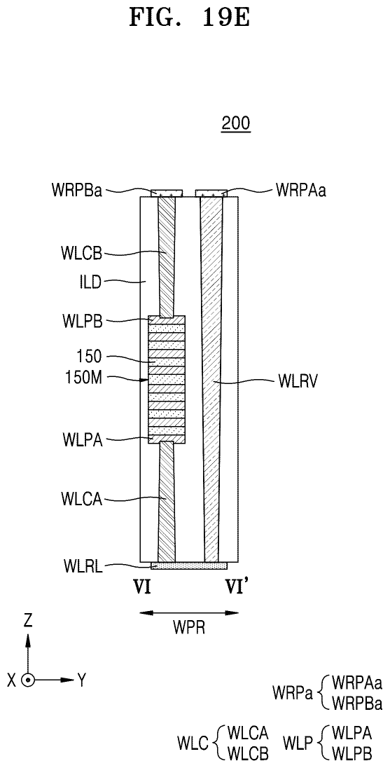

FIGS. 19A to 19E are plan layout views and cross-sectional views illustrating a semiconductor memory device 200 according to example embodiments. In detail, FIG. 19A is a top-down plan layout view of the semiconductor memory device 200 according to embodiments, FIG. 19B is a bottom-up plan layout view of the semiconductor memory device 200 according to embodiments, FIG. 19C is a cross-sectional view of the semiconductor memory device 200, taken along a line IV-IV′ of FIGS. 19A and 19B, FIG. 19D is a cross-sectional view of the semiconductor memory device 200, taken along a line V-V′ of FIGS. 19A and 19B, and FIG. 19E is a cross-sectional view of the semiconductor memory device 200, taken along a line VI-VI′ of FIGS. 19A and 19B.

Referring to FIGS. 19A to 19E together, the semiconductor memory device 200 may include a plurality of word lines WL and a plurality of bit lines BL. The plurality of word lines WL may include a plurality of word line pad portions WLP. The plurality of word lines WL may include a plurality of first word lines WLA and a plurality of second word lines WLB. The plurality of word line pad portions WLP may include a plurality of first word line pad portions WLPA included in the plurality of first word lines WLA, and a plurality of second word line pad portions WLPB included in the plurality of second word lines WLB.

A first word line contact WLCA may be connected to the first word line pad portion WLPA, and a second word line contact WLCB may be connected to the second word line pad portion WLPB. The plurality of word lines WL may be electrically connected to a plurality of routing pads WRPa through the plurality of word line contacts WLC. The plurality of routing pads WRPa may include a plurality of first routing pads WRPAa connected on the plurality of first word lines WLA and a plurality of second routing pads WRPBa connected on the plurality of second word lines WLB. The first routing pad WRPAa and the second routing pad WRPBa may be at the same vertical level. A word line routing via WLRV may be arranged between the word lines WL, that is, between the word line pad portions WLP, adjacent to each other in the second horizontal direction (Y direction) in the pad region WPR. A word line routing line WLRLb may be connected below each of the first word line contact WLCA and the word line routing via WLRV. The word line routing line WLRLb may electrically connect the first word line contact WLCA to the word line routing via WLRV.

The first word line contact WLCA may connect between the first word line pad portion WLPA of the first word line WLA and the first routing pad WRPAa. For example, an upper end of the first word line contact WLCA may be connected to the first word line pad portion WLPA of the first word line WLA, and a lower end of the first word line contact WLCA may be connected to the word line routing line WLRLb. A word line routing via WLRV may be formed between the word line routing line WLRLb and the first routing pad WRPAa. The first word line pad portion WLPA of the first word line WLA may be electrically connected to the first routing pad WRPAa through the first word line contact WLCA, the word line routing line WLRLb, and the word line routing via WLRV.

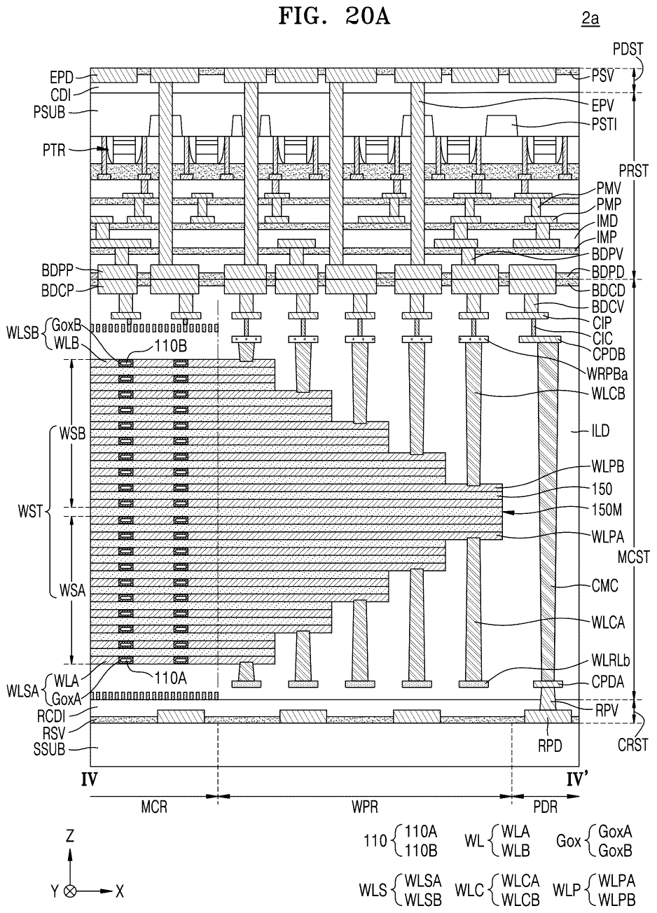

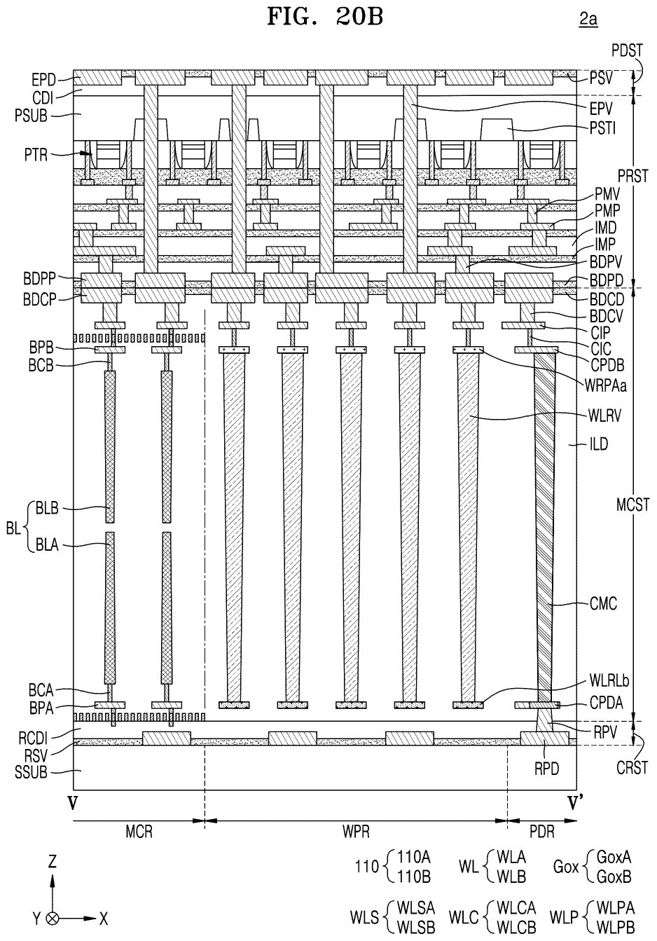

FIGS. 20A and 20B are cross-sectional views illustrating a semiconductor memory device 2a according to example embodiments. In detail, FIG. 20A is a cross-sectional view of the semiconductor memory device 2a, taken along a position corresponding to the line IV-IV′ of FIGS. 19A and 19B, and FIG. 20B is a cross-sectional view of the semiconductor memory device 2a, taken along a position corresponding to the line V-V′ of FIGS. 19A and 19B.

Referring to FIGS. 20A and 20B together, the semiconductor memory device 2a may have a memory cell region MCR, a pad region WPR, and an external connection region PDR that are arranged in the first horizontal direction (X direction). The semiconductor memory device 2a may include a cell routing structure CRST above a support substrate SSUB, a memory cell structure MCST above the cell routing structure CRST, a peripheral circuit structure PRST above the memory cell structure MCST, and a pad structure PDST above the peripheral circuit structure PRST.

The cell routing structure CRST may include a cell routing pad RPD above the support substrate SSUB, a cell routing via RPV connecting the cell routing pad RPD to the lower cell-peripheral circuit connection pad CPDA, and a cell routing cover insulation layer RCDI surrounding the cell routing pad RPD and the cell routing via RPV. In some embodiments, the cell routing via RPV may be formed to extend into the interlayer insulation layer ILD of the memory cell structure MCST. In some embodiments, a cell routing protective insulation layer RSV may be arranged below the cell routing cover insulation layer RCDI. The cell routing cover insulation layer RCDI may include oxide, and the cell routing protective insulation layer RSV may include nitride.

Unlike the memory cell structure MCST included in the semiconductor memory device 1a shown in FIGS. 7A and 7B, wherein the first routing pad WRPA and the second routing pad WRPB are respectively connected below the first word line contact WLCA and the word line routing via WLRV, and the word line routing line WLRL is connected on each of the second word line contact WLCB and the word line routing via WLRV, in the memory cell structure MCST included in the semiconductor memory device 2a shown in FIGS. 20A and 20B, the word line routing line WLRLb may be connected below each of the first word line contact WLCA and the word line routing via WLRV, and the first routing pad WRPAa and the second routing pad WRPBa may be respectively connected on the second word line contact WLCB and the word line routing via WLRV.

The cell bonding pad BDCP, the cell bonding insulation layer BDCD, the cell bonding via BDCV, the cell connection contact CIC, and the cell connection pattern CIP included in the semiconductor memory device 2a may have shapes in which the cell bonding pad BDCP, the cell bonding insulation layer BDCD, the cell bonding via BDCV, the cell connection contact CIC, and the cell connection pattern CIP included in the semiconductor memory device 1a shown in FIGS. 7A and 7B are turned over. The cell connection contact CIC may be connected to one of the upper cell-peripheral circuit connection pad CPDB, the second bit line connection pattern BPB, the first routing pad WRPAa, and the second routing pad WRPBa.

The peripheral circuit structure PRST included in the semiconductor memory device 2a may have a shape in which the peripheral circuit structure PRST shown in FIGS. 7A and 7B is turned over.

The pad structure PDST may include an external connection pad EPD above the Peripheral circuit structure PRST, an external connection via EPV connecting the external connection pad EPD to the peripheral circuit bonding pad BDPP, and a cover insulation layer CDI surrounding the external connection pad EPD and the external connection via EPV. In some embodiments, the external connection via EPV may penetrate the peripheral circuit substrate PSUB, the peripheral circuit device isolation film PSTI, the peripheral circuit wiring insulation layer IMD, and the peripheral circuit wiring protection layer IMP to be connected to the peripheral circuit bonding pad BDPP.

For example, the semiconductor memory device 2a may have a periphery-on-cell (PoC)-face structure in which the peripheral circuit structure PRST is arranged above the memory cell structure MCST, and an active surface of the peripheral circuit substrate PSUB and the plurality of peripheral circuit transistors PTR face the memory cell structure MCST.

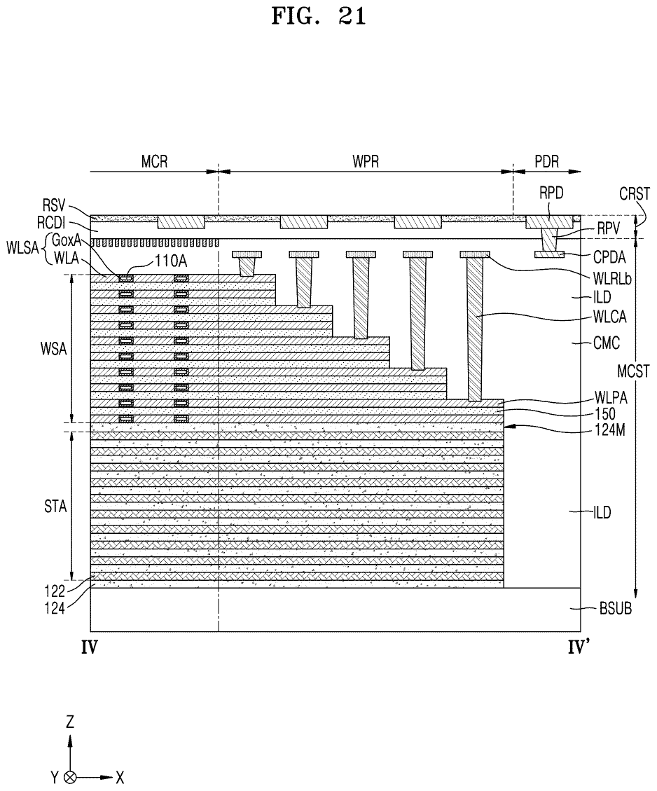

FIGS. 21 to 25 are cross-sectional views illustrating a method of manufacturing a semiconductor memory device, according to example embodiments. In detail, FIGS. 21 to 25 are cross-sectional views taken along a position corresponding to a line IV-IV′ of FIGS. 20A and 20B.

Referring to FIG. 21, with reference to FIG. 9A, a plurality of first word lines WLA, a plurality of first semiconductor patterns 110A, a plurality of first gate dielectric films GoxA, an interlayer insulation layer ILD, insulation layers 150, a plurality of first word line contacts WLCA, a lower cell-peripheral circuit connection pad CPDA, and a word line routing line WLRLb may be formed, and a cell routing structure CRST including a cell routing pad RPD, a cell routing via RPV, a cell routing cover insulation layer RCDI, and a cell routing protective insulation layer RSV may be formed above the interlayer insulation layer ILD.

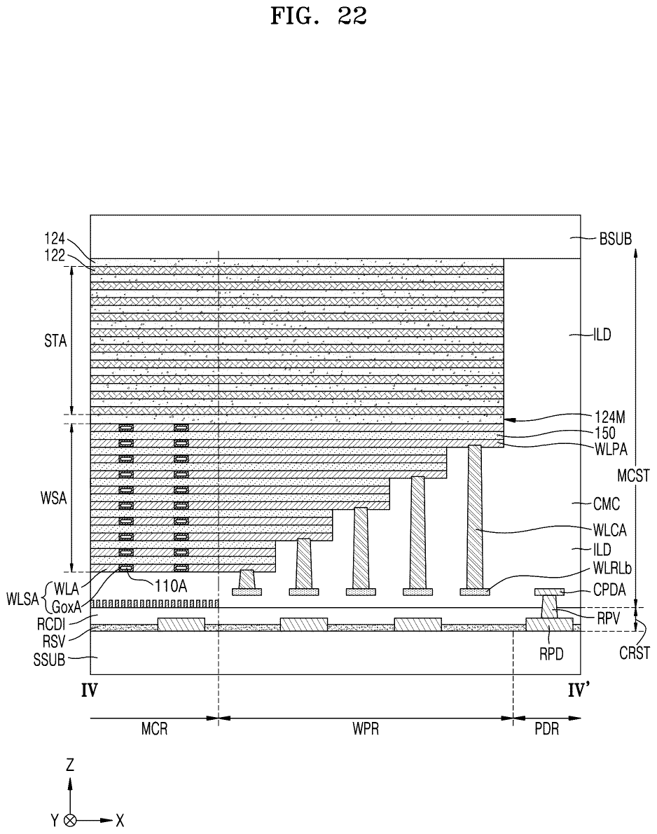

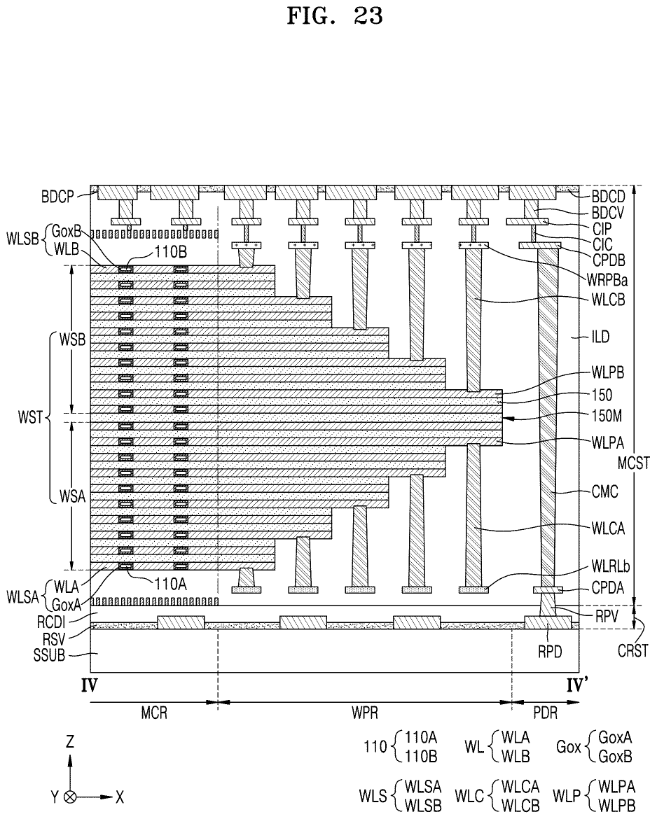

Referring to FIGS. 22 and 23 together, after the result of FIG. 21 is turned over and attached onto a support substrate SSUB, the base substrate BSUB may be removed. Thereafter, with reference to FIG. 9A, a plurality of second word lines WLB, a plurality of second semiconductor patterns 110B, a plurality of second gate dielectric films GoxB, an interlayer insulation layer ILD, insulation layers 150, a plurality of second word line contacts WLCB, an upper cell-peripheral circuit connection pad CPDB, a cell wiring contact CMC, an upper cell-peripheral circuit connection pad CPDB, a plurality of cell connection contacts CIC, a plurality of cell connection patterns CIP, a cell bonding via BDCV, a cell bonding pad BDCP, and a cell bonding insulation layer BDCD may be formed.

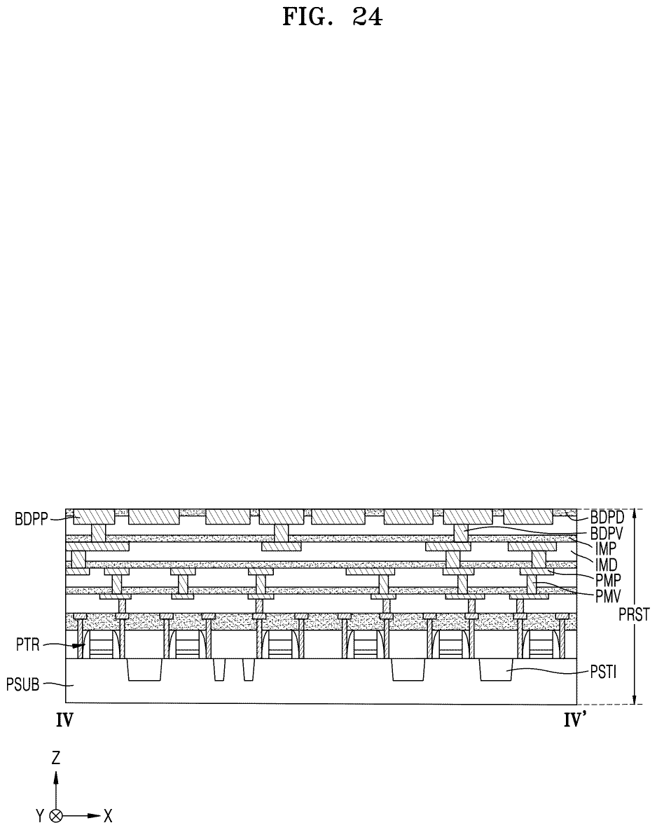

Referring also to FIG. 24, a peripheral circuit structure PRST including a peripheral circuit substrate PSUB, a plurality of peripheral circuit transistors PTR, a plurality of peripheral circuit connection patterns PMP, a plurality of peripheral circuit connection vias PMV, a peripheral circuit wiring insulation layer IMD, a peripheral circuit wiring protection layer IMP, a peripheral circuit bonding via BDPV, a peripheral circuit bonding pad BDPP, and a peripheral circuit bonding insulation layer BDPD may be formed.

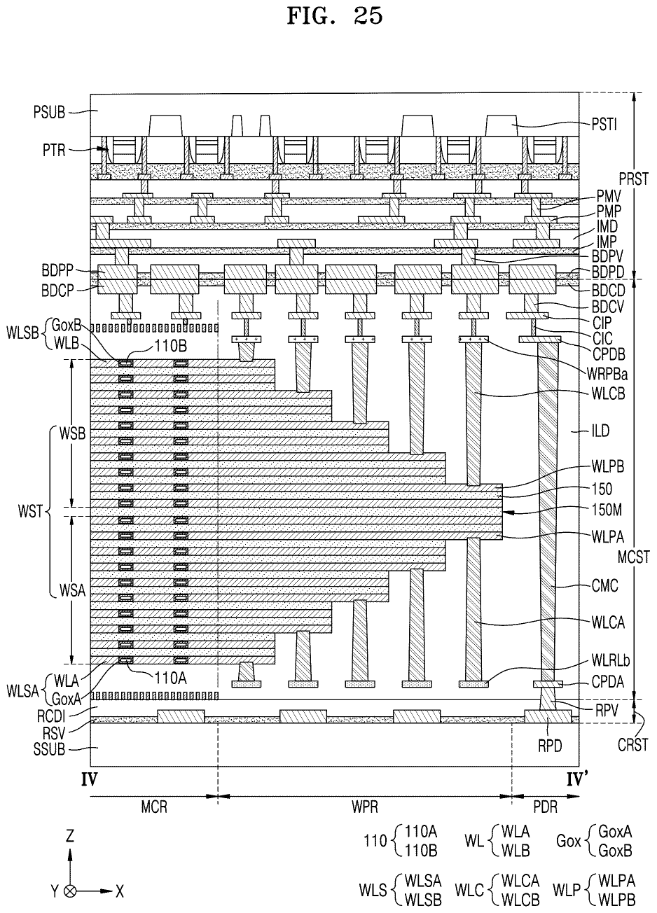

Referring to FIG. 25, the result of FIG. 24 may be turned over and attached onto the result of FIG. 23. That is, the peripheral circuit structure PRST may be attached onto the memory cell structure MCST. Thereafter, with reference to FIGS. 20A and 20B, a pad structure PDST may be formed above the peripheral circuit structure PRST, thereby forming a semiconductor memory device 2a.

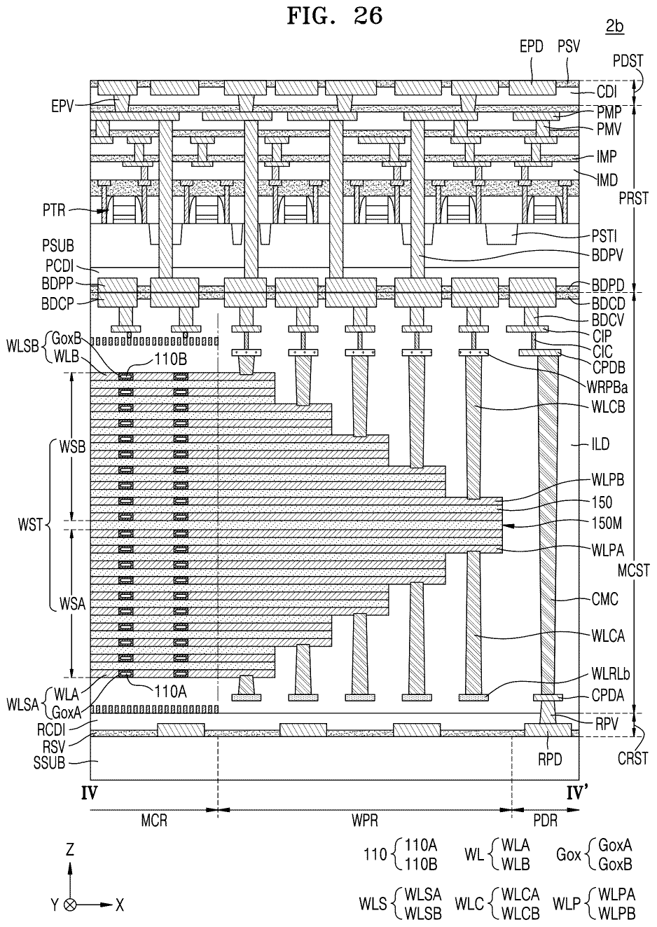

FIG. 26 is a cross-sectional view illustrating a semiconductor memory device 2b according to example embodiments. In detail, FIG. 26 is a cross-sectional view of the semiconductor memory device 2b, taken along a position corresponding to the line IV-IV′ of FIGS. 19A and 19B.

Referring to FIG. 26, the semiconductor memory device 2b may have a memory cell region MCR, a pad region WPR, and an external connection region PDR that are arranged in the first horizontal direction (X direction). The semiconductor memory device 2b may include a cell routing structure CRST above a support substrate SSUB, a memory cell structure MCST above the cell routing structure CRST, a peripheral circuit structure PRST above the memory cell structure MCST, and a pad structure PDST above the peripheral circuit structure PRST. The cell routing structure CRST and the memory cell structure MCST may be substantially the same as the cell routing structure CRST and the memory cell structure MCST shown in FIGS. 20A and 20B, and the peripheral circuit structure PRST may have a shape in which the peripheral circuit structure PRST shown in FIG. 17 is turned over.

The pad structure PDST may include an external connection pad EPD above the peripheral circuit structure PRST, an external connection via EPV connecting the external connection pad EPD to the peripheral circuit connection pattern PMP, and a cover insulation layer CDI surrounding the external connection pad EPD and the external connection via EPV. In some embodiments, the external connection via EPV may be formed to extend into the interlayer insulation layer ILD of the memory cell structure MCST. In some embodiments, a protective insulation layer PSV may be arranged above the cover insulation layer CDI.

For example, the semiconductor memory device 2b may have a PoC-back structure in which the peripheral circuit structure PRST is arranged above the memory cell structure MCST, a lower surface of the peripheral circuit substrate PSUB, which is an inactive surface of the peripheral circuit substrate PSUB, faces the memory cell structure MCST, and the plurality of peripheral circuit transistors PTR face away from the memory cell structure MCST.

After forming a cell routing structure CRST and a memory cell structure MCST with reference to FIGS. 21 to 23 and forming a peripheral circuit structure PRST with reference to FIGS. 14 to 17, the result of FIG. 17 may be turned over and attached onto the memory cell structure MCST, and a pad structure PDST may be formed above the peripheral circuit structure PRST, thereby forming a semiconductor memory device 2b.

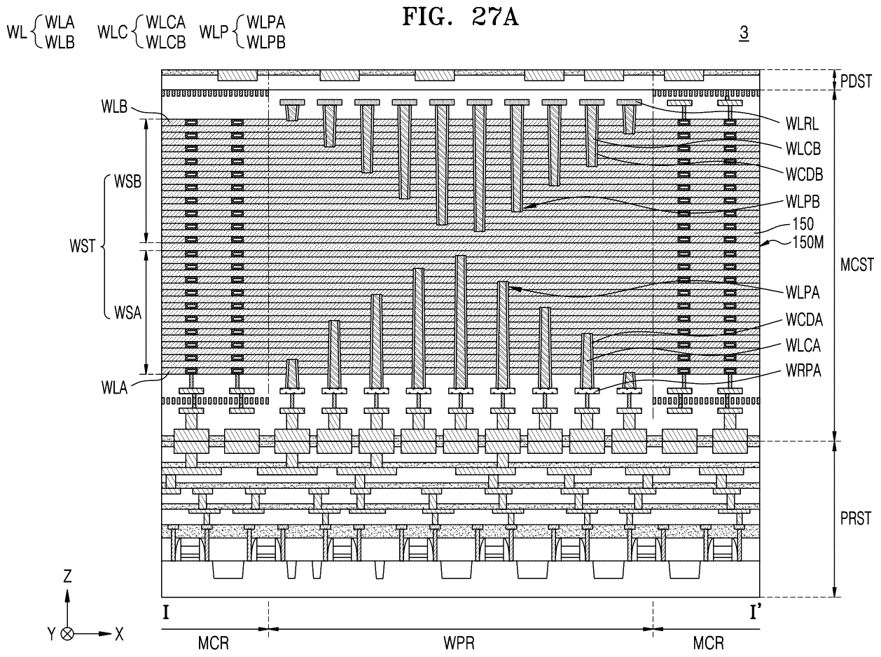

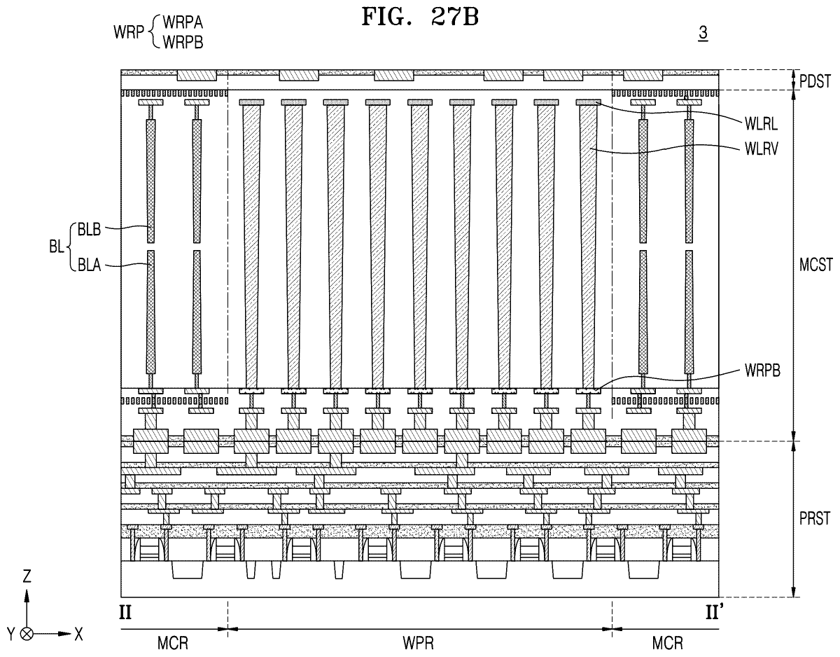

FIGS. 27A and 27B are cross-sectional views illustrating a semiconductor memory device 3 according to embodiments. In detail, FIG. 27A is a cross-sectional view of the semiconductor memory device 3, taken along a portion including a position corresponding to the line I-I′ of FIGS. 3A and 3B, and FIG. 27B is a cross-sectional view of the semiconductor memory device 3, taken along a portion including a position corresponding to the line II-II′ of FIGS. 3A and 3B.

Referring to FIGS. 27A and 27B together, the semiconductor memory device 3 may have memory cell regions MCR arranged spaced apart from each other in the first horizontal direction (X direction), and a pad region WPR arranged between two memory cell regions MCR adjacent to each other in the first horizontal direction (X direction). The semiconductor memory device 3 may include a peripheral circuit structure PRST, a memory cell structure MCST above the peripheral circuit structure PRST, and a pad structure PDST above the memory cell structure MCST, but is not limited thereto. For example, the semiconductor memory device 3 may be modified like the semiconductor memory devices 1a, 1b, 2a, and 2b described with reference to FIGS. 3A to 26. The semiconductor memory device 3 may include a plurality of word lines WL and a plurality of bit lines BL.

The plurality of word lines WL may include a plurality of first word lines WLA and a plurality of second word lines WLB. The plurality of word lines WL may constitute a word line stack WST. The word line stack WST may include a first word line stack WSA and a second word line stack WSB above the first word line stack WSA. The first word line stack WSA may include the plurality of first word lines WLA among the plurality of word lines WL, and the second word line stack WSB may include the plurality of second word lines WLB among the plurality of word lines WL. The plurality of word lines WL may include a plurality of word line pad portions WLP. The plurality of word line pad portions WLP may include a plurality of first word line pad portions WLPA included in the plurality of first word lines WLA, and a plurality of second word line pad portions WLPB included in the plurality of second word lines WLB. The plurality of word lines WL may have substantially the same extension length in the first horizontal direction (X direction). The plurality of word lines WL may extend continuously along two memory cell regions MCR adjacent to each other in the first horizontal direction (X direction) and the pad region WPR arranged between the two memory cell regions MCR.

A first word line contact WLCA may be connected to the first word line pad portion WLPA, and a second word line contact WLCB may be connected to the second word line pad portion WLPB. The plurality of word lines WL may be electrically connected to a plurality of routing pads WRP through the plurality of word line contacts WLC. The plurality of routing pads WRP may include a plurality of first routing pads WRPA connected below the plurality of first word lines WLA and a plurality of second routing pads WRPB connected below the plurality of second word lines WLB. A word line routing via WLRV may be arranged between the word lines WL, that is, between the word line pad portions WLP, adjacent to each other in the second horizontal direction (Y direction) in the pad region WPR. A word line routing line WLRL may be connected on each of the second word line contact WLCB and the word line routing via WLRV. The word line routing line WLRL may electrically connect the second word line contact WLCB to the word line routing via WLRV.

The first word line contact WLCA connected to a first word line WLA other than the lowermost first word line WLA among the plurality of first word lines WLA may penetrate at least one first word line WLA located below the first word line WLA to which the first word line contact WLCA is connected. The second word line contact WLCB connected to a second word line WLB other than the uppermost second word line WLB among the plurality of second word lines WLB may penetrate at least one second word line WLB located above the second word line WLB to which the second word line contact WLCB is connected. A first contact insulation film WCDA may surround a sidewall of the first word line contact WLCA, and a second contact insulation film WCDB may surround a sidewall of the second word line contact WLCB. The first contact insulation film WCDA may be arranged between the first word line contact WLCA and the first word line WLA through which the first word line contact WLCA penetrates, and the second contact insulation film WCDB may be arranged between the second word line contact WLCB and the second word line WLB through which the second word line contact WLCB penetrates.

The plurality of bit lines BL may include a plurality of first bit lines BLA and a plurality of second bit lines BLB. The plurality of first bit lines BLA may extend in the vertical direction (Z direction) through the plurality of first word lines WLA, and the plurality of second bit lines BLB may extend in the vertical direction (Z direction) through the plurality of second word lines WLB.

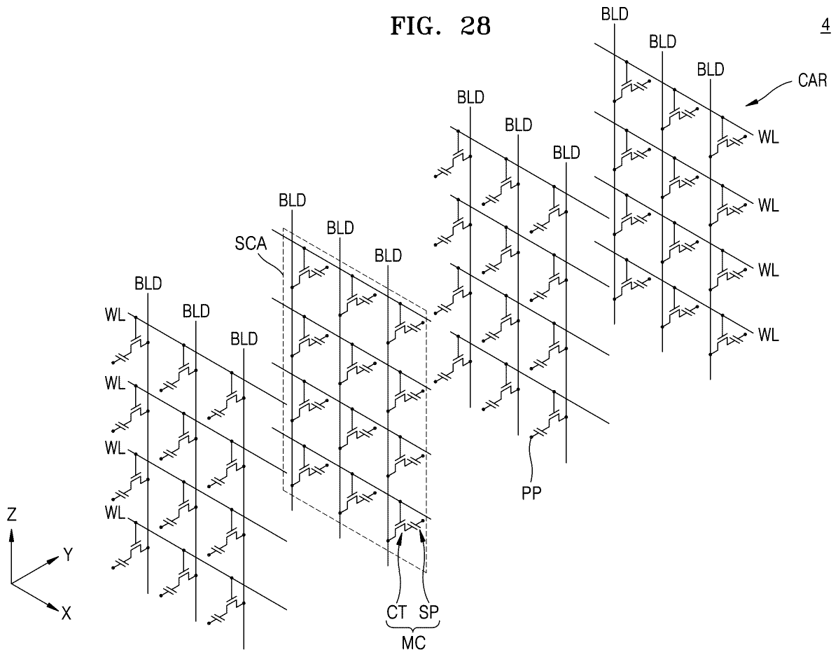

FIG. 28 is an equivalent circuit diagram illustrating a memory cell array of a semiconductor memory device 4 according to example embodiments.

Referring to FIG. 28, the memory cell array of the semiconductor memory device 4 according to embodiments may include a plurality of sub-cell arrays SCA. The sub-cell array SCA may include a plurality of bit lines BLD, a plurality of word lines WL, and a plurality of memory cells MC. Each of the plurality of memory cells MC may include a cell transistor CT and an information storage element SP. One cell transistor CT may be arranged between one word line WL and one bit line BLD. The plurality of sub-cell arrays SCA may be arranged in the second horizontal direction (Y direction).

The plurality of word lines WL may extend in the first horizontal direction (X direction). The word lines WL within one sub-cell array SCA may be spaced apart from each other in the vertical direction (Z direction). The bit line BLD may extend in the vertical direction (Z direction). The bit lines BLD within one sub-cell array SCA may be spaced apart from each other in the first horizontal direction (X direction).

A gate of the cell transistor CT may be connected to the word line WL, and a source region of the cell transistor CT may be connected to the bit line BLD. The information storage element SP may be connected to a drain region of the cell transistor CT.

A pair of bit lines BLD adjacent to each other in the second horizontal direction (Y direction) may perform substantially the same function as one bit line BL shown in FIG. 1. For example, when one bit line BL shown in FIG. 1 is separated into two bit lines BL that are spaced apart from each other in the second horizontal direction (Y direction), the two bit lines BL may become a pair of bit lines BLD that are adjacent to each other in the second horizontal direction (Y direction), as shown in FIG. 28. The source region and drain region of the cell transistor CT and the information storage element SP may be arranged in the second horizontal direction (Y direction) or a direction opposite to the second horizontal direction (Y direction), from the bit line BLD connected to the source region of the cell transistor CT. The source regions and drain regions of the cell transistors CT, which are respectively connected to two bit lines BLD adjacent to each other in the second horizontal direction (Y direction), and the information storage elements SP respectively connected to the cell transistors CT may be arranged in opposite directions. For example, the source region and drain region of the cell transistor CT, which is connected to one of the two bit lines BLD adjacent to each other in the second horizontal direction (Y direction), and the information storage element SP connected to the cell transistor CT may be sequentially arranged in the second horizontal direction (Y direction), and the source region and drain region of the cell transistor CT, which is connected to the other bit line BLD, and the information storage element SP connected to the cell transistor CT may be sequentially arranged in a direction opposite to the second horizontal direction (Y direction). For example, the plurality of bit lines BLD may include a first bit line, a second bit line, a third bit line, and a fourth bit line that are sequentially arranged adjacent to each other in the second horizontal direction (Y direction), wherein a memory cell MC may not be arranged between the first bit line and the second bit line, two memory cells MC may be arranged between the second bit line and the third bit line at the same vertical level in the second horizontal direction (Y direction), and a memory cell MC may not be arranged between the third bit line and the fourth bit line.

While the inventive concept has been particularly shown and described with reference to embodiments thereof, it will be understood that various changes in form and details may be made therein without departing from the spirit and scope of the following claims.

What is claimed is:

1. A semiconductor memory device having a memory cell region and a pad region that are arranged in a first horizontal direction, the semiconductor memory device comprising:
a first word line stack comprising a plurality of first word lines extending in the first horizontal direction, being spaced apart from each other in each of a second horizontal direction and a vertical direction, and comprising a plurality of first word line pad portions in the pad region, the second horizontal direction being orthogonal to the first horizontal direction;
a second word line stack comprising a plurality of second word lines and overlapping the first word line stack in the vertical direction, the plurality of second word lines extending in the first horizontal direction, being spaced apart from each other in each of the second horizontal direction and the vertical direction, and comprising a plurality of second word line pad portions in the pad region;
a plurality of first word line contacts extending in the vertical direction and having ends connected to the plurality of first word line pad portions;
a plurality of second word line contacts extending in the vertical direction and having ends connected to the plurality of second word line pad portions;
a plurality of word line routing vias extending in the vertical direction and being spaced apart from each of the plurality of first word lines and the plurality of second word lines, in the pad region;
a plurality of word line routing lines connecting ends of the plurality of word line routing vias to other ends of the plurality of second word line contacts;
a plurality of first routing pads connected to other ends of the plurality of first word line contacts; and
a plurality of second routing pads connected to other ends of the plurality of word line routing vias.

2. The semiconductor memory device of claim 1, wherein the plurality of first routing pads and the plurality of second routing pads are located at a same vertical level.

3. The semiconductor memory device of claim 1,
wherein the plurality of first word line contacts have tapered shapes in which horizontal widths of the plurality of first word line contacts increase away from the plurality of first word line pad portions, and
wherein the plurality of second word line contacts have tapered shapes in which horizontal widths of the plurality of second word line contacts increase away from the plurality of second word line pad portions.

4. The semiconductor memory device of claim 1,
wherein the second word line stack is located above the first word line stack,
wherein the plurality of first word line contacts extend downward from lower surfaces of the plurality of first word line pad portions, and
wherein the plurality of second word line contacts extend upward from upper surfaces of the plurality of second word line pad portions.

5. The semiconductor memory device of claim 4, wherein the plurality of word line routing vias have tapered shapes in which horizontal widths of the plurality of word line routing vias decrease away from the plurality of word line routing lines.

6. The semiconductor memory device of claim 1,
wherein the first word line stack is located above the second word line stack,
wherein the plurality of first word line contacts extend upward from upper surfaces of the plurality of first word line pad portions, and
wherein the plurality of second word line contacts extend downward from lower surfaces of the plurality of second word line pad portions.

7. The semiconductor memory device of claim 6, wherein the plurality of word line routing vias have tapered shapes in which horizontal widths of the plurality of word line routing vias increase away from the plurality of word line routing lines.

8. The semiconductor memory device of claim 1, further comprising:
a plurality of first bit lines extending in the vertical direction between the plurality of first word lines; and
a plurality of second bit lines extending in the vertical direction between the plurality of second word lines,
wherein, among the plurality of first bit lines and the plurality of second bit lines, a first bit line and a second bit line that are aligned in the vertical direction have tapered shapes in which horizontal widths of the first bit line and the second bit line decrease toward each other.

9. The semiconductor memory device of claim 8, wherein, among the plurality of first bit lines and the plurality of second bit lines, the first bit line and the second bit line that are aligned in the vertical direction are in contact with each other.

10. The semiconductor memory device of claim 8, wherein, among the plurality of first bit lines and the plurality of second bit lines, the first bit line and the second bit line that are aligned in the vertical direction are spaced apart from each other in the vertical direction.

11. A semiconductor memory device having a memory cell region and a pad region that are arranged in a first horizontal direction, the semiconductor memory device comprising:
a memory cell structure; and
a peripheral circuit structure stacked perpendicular to the memory cell structure and electrically connected to the memory cell structure,
wherein the peripheral circuit structure comprises:
a peripheral circuit substrate; and
a plurality of peripheral circuit transistors located on an active surface of the peripheral circuit substrate, and
wherein the memory cell structure comprises:
a first word line stack comprising a plurality of first word lines extending in the first horizontal direction, being spaced apart from each other in each of a second horizontal direction and a vertical direction, and comprising a plurality of first word line pad portions in the pad region, the second horizontal direction being orthogonal to the first horizontal direction;
a second word line stack comprising a plurality of second word lines and overlapping the first word line stack in the vertical direction, the plurality of second word lines extending in the first horizontal direction, being spaced apart from each other in each of the second horizontal direction and the vertical direction, and comprising a plurality of second word line pad portions in the pad region;
a plurality of first word line contacts extending in the vertical direction and having ends connected to the plurality of first word line pad portions;
a plurality of second word line contacts extending in the vertical direction and having ends connected to the plurality of second word line pad portions;
a plurality of word line routing vias extending in the vertical direction and being spaced apart from each of the plurality of first word lines and the plurality of second word lines, in the pad region;
a plurality of word line routing lines connecting ends of the plurality of word line routing vias to other ends of the plurality of second word line contacts;
a plurality of first routing pads connected to other ends of the plurality of first word line contacts; and
a plurality of second routing pads connected to other ends of the plurality of word line routing vias.

12. The semiconductor memory device of claim 11,
wherein the second word line stack is located above the first word line stack, and
wherein the peripheral circuit structure is located below the memory cell structure.

13. The semiconductor memory device of claim 12,
wherein the plurality of first routing pads and the plurality of second routing pads are located at a same vertical level below the first word line stack, and
wherein the peripheral circuit structure is electrically connected to the memory cell structure through the plurality of first routing pads and the plurality of second routing pads.

14. The semiconductor memory device of claim 11,
wherein the second word line stack is located below the first word line stack, and
wherein the peripheral circuit structure is located above the memory cell structure.

15. The semiconductor memory device of claim 14,
wherein the plurality of first routing pads and the plurality of second routing pads are located at a same vertical level above the first word line stack, and
wherein the peripheral circuit structure is electrically connected to the memory cell structure through the plurality of first routing pads and the plurality of second routing pads.

16. The semiconductor memory device of claim 11,
wherein the plurality of first word line contacts have tapered shapes in which horizontal widths of the plurality of first word line contacts increase away from the plurality of first word line pad portions, and
wherein the plurality of second word line contacts have tapered shapes in which horizontal widths of the plurality of second word line contacts increase away from the plurality of second word line pad portions.

17. The semiconductor memory device of claim 11, wherein the plurality of word line routing vias have tapered shapes in which horizontal widths of the plurality of word line routing vias decrease from upper sides to lower sides thereof.

18. The semiconductor memory device of claim 11,
wherein a plurality of word line contacts comprising the plurality of first word line contacts and the plurality of second word line contacts are arranged in a line in the first horizontal direction,
wherein the plurality of word line routing vias are arranged in a line in the first horizontal direction, and
wherein the plurality of word line contacts and the plurality of word line routing vias are alternately arranged in a line in the second horizontal direction.

19. The semiconductor memory device of claim 12,
wherein a plurality of word line contacts comprising the plurality of first word line contacts and the plurality of second word line contacts are arranged in a line in the first horizontal direction,
wherein the plurality of word line routing vias are arranged in a line in the first horizontal direction, and
wherein the plurality of word line contacts and the plurality of word line routing vias are alternately arranged in a line in a diagonal direction with respect to the first horizontal direction and the second horizontal direction.

20. A semiconductor memory device having a memory cell region and a pad region that are arranged in a first horizontal direction, the semiconductor memory device comprising:
a memory cell structure; and
a peripheral circuit structure stacked perpendicular to the memory cell structure and electrically connected to the memory cell structure,
wherein the peripheral circuit structure comprises:
a peripheral circuit substrate; and
a plurality of peripheral circuit transistors located on an active surface of the peripheral circuit substrate, and
wherein the memory cell structure comprises:
a first word line stack comprising a plurality of first word lines extending in the first horizontal direction, being spaced apart from each other in each of a second horizontal direction and a vertical direction, and comprising a plurality of first word line pad portions in the pad region, the second horizontal direction being orthogonal to the first horizontal direction;
a second word line stack comprising a plurality of second word lines and overlapping the first word line stack in the vertical direction, the plurality of second word lines extending in the first horizontal direction, being spaced apart from each other in each of the second horizontal direction and the vertical direction, and comprising a plurality of second word line pad portions in the pad region;
a plurality of first bit lines extending in the vertical direction between the plurality of first word lines;
a plurality of second bit lines extending in the vertical direction between the plurality of second word lines;
a plurality of first word line contacts connected to lower surfaces of the plurality of first word line pad portions and extending in the vertical direction;
a plurality of second word line contacts connected to upper surfaces of the plurality of second word line pad portions and extending in the vertical direction;
a plurality of word line routing vias extending in the vertical direction between first word lines spaced apart from each other in the second horizontal direction, among the plurality of first word lines, and between second word lines spaced apart from each other in the second horizontal direction, among the plurality of second word lines, in the pad region;
a plurality of word line routing lines connecting upper ends of the plurality of second word line contacts to upper ends of the plurality of word line routing vias;
a plurality of first routing pads connected to lower ends of the plurality of first word line contacts; and
a plurality of second routing pads connected to lower ends of the plurality of word line routing vias and electrically connected to the plurality of second word line contacts,
wherein the plurality of first word line contacts have tapered shapes in which horizontal widths of the plurality of first word line contacts increase away from the plurality of first word line pad portions,
wherein the plurality of second word line contacts have tapered shapes in which horizontal widths of the plurality of second word line contacts increase away from the plurality of second word line pad portions, and
wherein the plurality of word line routing vias have tapered shapes in which horizontal widths of the plurality of word line routing vias decrease from the plurality of word line routing lines to the plurality of second routing pads.
